(19) United States
(12) Patent Application Publication
(10) Pub. No.: US 2026/0114039 A1
(43) Pub. Date: Apr. 23, 2026

(54) SEMICONDUCTOR DEVICE

(71) Applicant: Samsung Electronics Co., Ltd., Suwon-si (KR)

(72) Inventors: WOOKHYUN KWON, Suwon-si (KR); MYUNG GIL KANG, Suwon-si (KR); SOOJIN JEONG, Suwon-si (KR); BYOUNG HAK HONG, Suwon-si (KR); Bumcheol Kim, Suwon-si (KR); Hyunmin Ahn, Suwon-si (KR)

(21) Appl. No.: 19/214,308

(22) Filed: May 21, 2025

(30) Foreign Application Priority Data
Oct. 23, 2024 (KR) 10-2024-0146002

(51) Int. Cl. H10D 84/85; H10D 30/00; H10D 30/01; H10D 30/43; H10D 62/10; H10D 62/13; H10D 64/23; H10D 84/01

(52) U.S. Cl. CPC H10D 84/851; H10D 30/43; H10D 30/502; H10D 62/116; H10D 62/121; H10D 62/151; H10D 64/256; H10D 84/856; H10D 30/014; H10D 30/0191; H10D 84/017

(57) ABSTRACT

The present disclosure relates to a semiconductor device, and a semiconductor device according to an embodiment includes a substrate that includes a first well region having a first conductivity type and a second well region having a second conductivity type, a first lower pattern positioned in the first well region, a second lower pattern positioned in the second well region, a first channel pattern positioned on the first lower pattern, a second channel pattern positioned on the second lower pattern, a gate structure that surrounds the first channel pattern and the second channel pattern, a first source/drain pattern positioned on opposite sides of the first channel pattern, a first well tap pattern positioned on opposite sides of the second channel pattern, and a first barrier pattern positioned between the first source/drain pattern and the first lower pattern.

### CROSS-REFERENCE TO RELATED APPLICATION

This application claims priority under 35 U.S.C. § 119 to Korean Patent Application No. 10-2024-0146002, filed Oct. 23, 2024, in the Korean Intellectual Property Office, and the benefit thereof, the entire contents of which are incorporated herein by reference.

### BACKGROUND

### 1. Field

The present disclosure relates to a semiconductor device.

### 2. Description of the Related Art

Semiconductors are materials falling within the intermediate category between conductors and nonconductors, and refer to materials conducting electricity under predetermined conditions. Such semiconductor materials can be used to manufacture various semiconductor devices, for example, to manufacture memory devices and so on. These semiconductor devices may be used in various electronic devices.

As the electronics industry has been further developing, the demands for the characteristics of semiconductor devices have been gradually increasing. For example, the demands for semiconductor devices with higher reliability, higher speed, and/or more functions have been gradually increasing. In order to obtain these required characteristics, the structures in semiconductor devices have gradually become complicated and have been integrated at higher densities. As the sizes of transistors decrease, coupling between elements may occur, whereby the degrees of reliability of semiconductor devices may decrease while the operating speeds of the semiconductor devices may decrease.

### SUMMARY

The present disclosure attempts to provide a semiconductor device with improved reliability.

A semiconductor device according to an embodiment includes a substrate that includes a first well region having a first conductivity type and a second well region having a second conductivity type, a first lower pattern positioned in the first well region, a second lower pattern positioned in the second well region, a first channel pattern positioned on the first lower pattern, a second channel pattern positioned on the second lower pattern, a gate structure that surrounds the first channel pattern and the second channel pattern, a first source/drain pattern positioned on opposite sides of the first channel pattern, a first well tap pattern positioned on opposite sides of the second channel pattern, and a first barrier pattern positioned between the first source/drain pattern and the first lower pattern.

A semiconductor device according to an embodiment includes a substrate that includes a first well region having a first conductivity type and a second well region having a second conductivity type, a first lower pattern positioned in the first well region, a second lower pattern positioned in the second well region, a first channel pattern positioned on the first lower pattern, a second channel pattern positioned on the second lower pattern, a gate structure that surrounds the first channel pattern and the second channel pattern, a first source/drain pattern positioned on opposite sides of the first channel pattern and has the second conductivity type, a first well tap pattern positioned on opposite sides of the second channel pattern and has the second conductivity type, and a first barrier pattern positioned between the first source/drain pattern and the first lower pattern, and the thickness of the first source/drain pattern is smaller than the thickness of the first well tap pattern.

A semiconductor device according to an embodiment includes a substrate that includes a first well region having a first conductivity type and a second well region having a second conductivity type, a first tap cell that is positioned in the first well region and has the second conductivity type, and a first logic cell that is positioned in the second well region and has the second conductivity type, and the first logic cell includes a first lower pattern positioned in the first well region, a first channel pattern positioned on the first lower pattern, a gate structure that surrounds the first channel pattern, a first source/drain pattern positioned on opposite sides of the first channel pattern, and a first barrier pattern positioned between the first source/drain pattern and the first lower pattern, and the first tap cell includes a second lower pattern positioned in the second well region, a second channel pattern positioned on the second lower pattern, and a first well tap pattern positioned on opposite sides of the second channel pattern and is in contact with the second lower pattern, and the lower surface of the first barrier pattern is positioned farther from the lower surface of the substrate than the lower surface of the first well tap pattern, or the lower surface of the first barrier pattern and the lower surface of the first well tap pattern are positioned at the same distance from the lower surface of the substrate.

According to the embodiment, it is possible to improve the reliability of the semiconductor device.

### BRIEF DESCRIPTION OF THE DRAWINGS

FIGS. 1 and 2 are plan views illustrating a semiconductor device according to an example embodiment.

FIG. 3 is a cross-sectional view taken along line A-A′ in FIG. 1.

FIG. 4 is a cross-sectional view taken along line B-B′ in FIG. 1.

FIG. 5 is a cross-sectional view illustrating region S1 and region S2 of FIG. 3.

FIGS. 6 to 12 are cross-sectional views illustrating semiconductor devices according to some example embodiments and corresponding to the region S1 and the region S2 of FIG. 3.

FIGS. 13 and 14 are cross-sectional views illustrating a semiconductor device according to some example embodiments and corresponding to line A-A′ of FIG. 1.

FIGS. 15 to 26 are cross-sectional views illustrating processes of an intermediate stage of a method of manufacturing the semiconductor device according to the example embodiment.

FIGS. 27 to 30 are cross-sectional views illustrating processes of an intermediate stage of a method of manufacturing the semiconductor device according to some example embodiments.

### DETAILED DESCRIPTION

In the following detailed description, only certain embodiments have been shown and described, simply by way of illustration. The present invention can be variously implemented and is not limited to the following embodiments.

The drawings and description are to be regarded as illustrative in nature and not restrictive. Like reference numerals designate like elements throughout the specification and drawings.

In addition, the size and thickness of each configuration shown in the drawings are arbitrarily shown for understanding and ease of description, but the present invention is not limited thereto. In the drawings, the thickness of layers, films, panels, regions, etc., are exaggerated for clarity. In the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In addition, throughout this specification, unless explicitly described to the contrary, the word “comprise”, and variations such as “comprises” or “comprising”, will be understood to imply the inclusion of stated elements but not the exclusion of any other elements.

Further, throughout this specification, when it is referred to as “on a plane”, it means when a target part is viewed from above, and when it is referred to as “on a cross-section”, it means when the cross-section obtained by cutting a target part vertically is viewed from the side.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

In the drawings related to a semiconductor device according to an embodiment, a transistor including a nano wire or a nano sheet, multi-bridge channel field effect transistor (MBCFET™), a fin transistor (FinFET) including a channel region having a fin-like pattern shape are shown as examples; however, the present disclosure is not limited thereto. It goes without saying that semiconductor devices according to some embodiments may include tunneling FETs, 3D stack field effect transistors (3DSFETs), complementary field effect transistors (CFETs), etc.

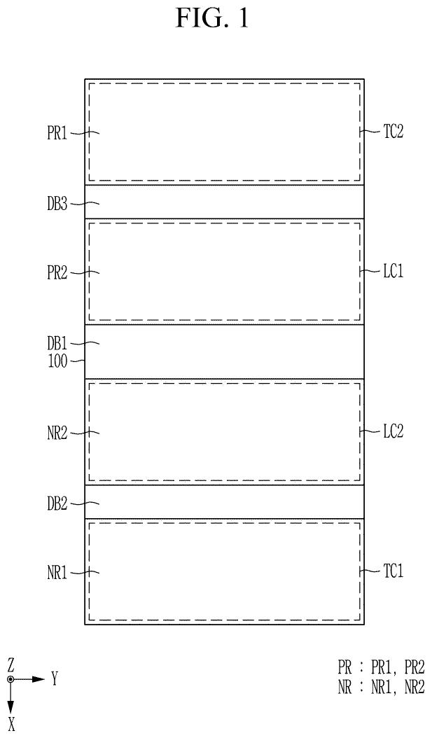

FIG. 1 is a plan view illustrating a semiconductor device according to an example embodiment.

Referring to FIG. 1, a semiconductor device according to an embodiment may include logic cells LC1 and LC2 and tap cells TC1 and TC2 provided on a substrate 100.

The logic cells LC1 and LC2 and the tap cells TC1 and TC2 may extend lengthwise in a second direction (a Y direction). The logic cells LC1 and LC2 and the tap cells TC1 and TC2 may be arranged so as to be spaced apart from each other in a first direction (an X direction). For example, the first logic cell LC1 and the second logic cell LC2 may be positioned between the first tap cell TC1 and the second tap cell TC2, but the present disclosure is not limited thereto. The logic cells LC1 and LC2 and the tap cells TC1 and TC2 may be defined by isolation structures DB1, DB2, and DB3. In other words, the logic cells LC1 and LC2 and the tap cells TC1 and TC2 may be isolated by the isolation structures DB1, DB2, and DB3. For example, the first isolation structure DB1 may be positioned between the first logic cell LC1 and the second logic cell LC2, the second isolation structure DB2 may be positioned between the second logic cell LC2 and the first tap cell TC1, and the third isolation structure DB3 may be positioned between the first logic cell LC1 and the second tap cell TC2; however, the present disclosure is not limited thereto.

The semiconductor device according to the embodiment includes the substrate 100 including a first well region PR and a second well region NR, and the logic cells LC1 and LC2 and the tap cells TC1 and TC2 may be positioned in the first well region PR and second well region NR of the substrate 100. For example, the first logic cell LC1 may be positioned in a second portion PR2 of the first well region PR, and the second logic cell LC2 may be positioned in a second portion NR2 of the second well region NR. Further, the first tap cell TC1 may be positioned in a first portion NR1 of the second well region NR, and the second tap cell TC2 may be positioned in a first portion PR1 of the first well region PR. Here, the first well region PR may be an n-MOSFET region, and the second well region NR may be a p-MOSFET region.

In this specification, the logic cells LC1 and LC2 may refer to logic devices (e.g., AND gates, OR gates, XOR gates, XNOR gates, inverters, etc.) for performing specific functions. In other words, the logic cells LC1 and LC2 may include transistors for constituting logic devices, and wires connecting the transistors to one another. As an example, the logic cells LC1 and LC2 may constitute a CMOS including one NMOSFET and one PMOSFET.

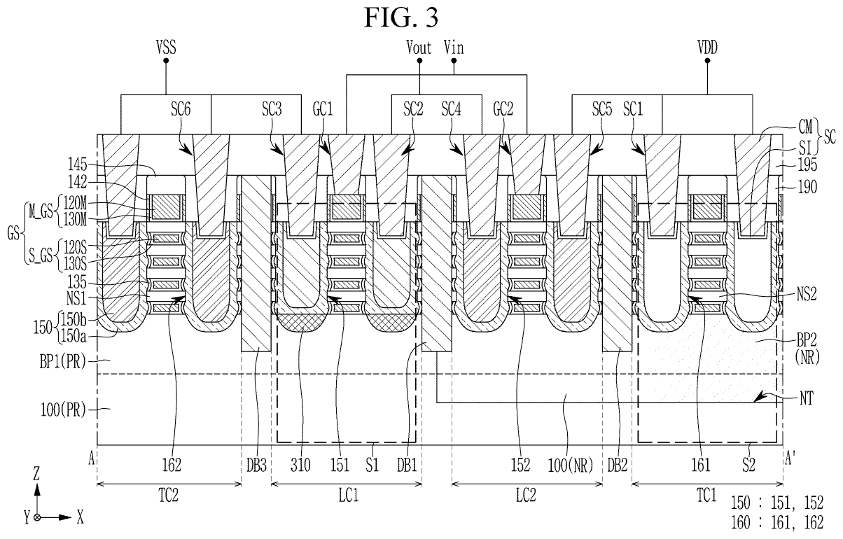

The tap cells TC1 and TC2 may be cells for applying voltage from a power transfer network to the substrate 100 and so on of the semiconductor device. For example, the first tap cell TC1 may apply a first power voltage (reference symbol “VDD” of FIG. 3) from the power transfer network to the substrate 100 of the semiconductor device, and the second tap cell TC2 may apply a second power voltage (reference symbol “VSS” of FIG. 3) from the power transfer network to the substrate 100 of the semiconductor device. The tap cells TC1 and TC2 may not include logic devices, unlike the logic cells LC1 and LC2. In other words, the tap cells TC1 and TC2 may be a type of dummy cells which performs a function of applying voltage to the substrate 100 and so on but does not perform any function in terms of circuit.

Although it is shown in FIG. 1 that the second tap cell TC2, the first logic cell LC1, the second logic cell LC2, and the first tap cell TC1 are sequentially arranged in the first direction (the X direction), the arrangement relationship of the logic cells LC1 and LC2 and the tap cells TC1 and TC2 may be variously changed. In an embodiment, predetermined passive elements may be further positioned between the logic cells LC1 and LC2 and the tap cells TC1 and TC2. For example, passive elements functioning as capacitors may be further positioned between the second tap cell TC2 and the first logic cell LC1 and between the second logic cell LC2 and the first tap cell TC1.

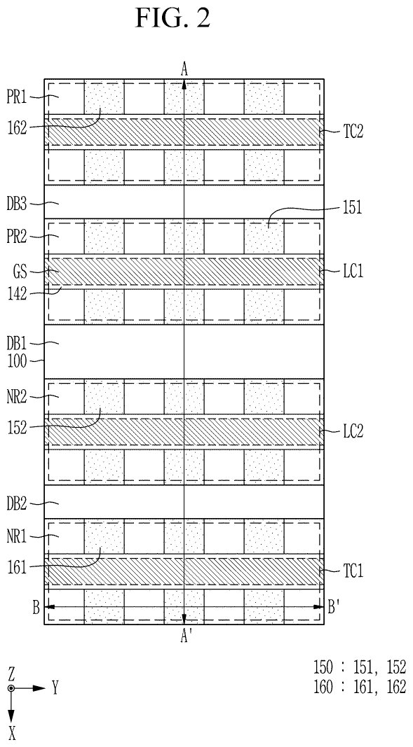

Hereinafter, the semiconductor device according to the embodiment will be described with reference to FIGS. 2 to 5 together.

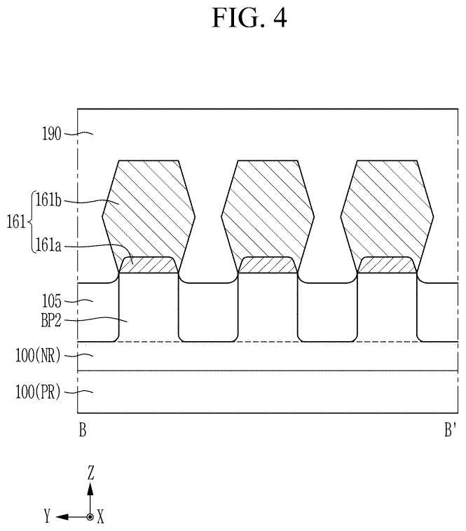

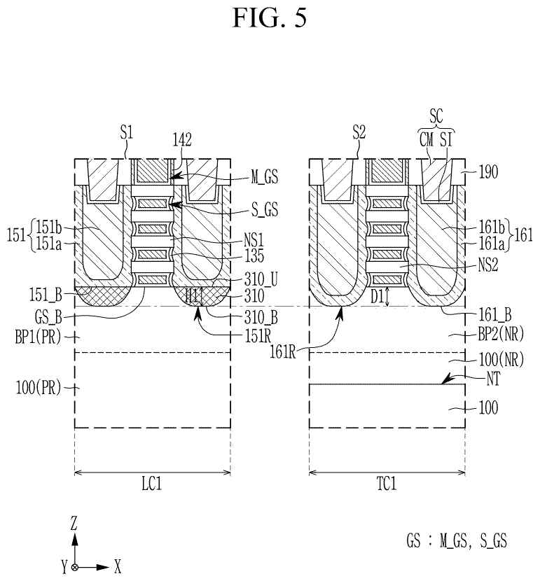

FIG. 2 is a plan view illustrating the semiconductor device according to the example embodiment. FIG. 3 is a cross-sectional view taken along line A-A′ in FIG. 1. FIG. 4 is a cross-sectional view taken along line B-B′ in FIG. 1. FIG. 5 is a cross-sectional view illustrating region S1 and region S2 of FIG. 3.

Referring to FIGS. 2 to 5 together, the semiconductor device according to the embodiment includes the substrate 100, lower patterns BP1 and BP2 that are positioned on the substrate 100, channel patterns NS1 and NS2 that are positioned on the lower patterns BP1 and BP2, a gate structure GS that surrounds the channel patterns NS1 and NS2, a source/drain pattern 150 and a well tap pattern 160 that are positioned on opposite sides of the channel patterns NS1 and NS2, and a first barrier pattern 310 that is positioned between a first source/drain pattern 151 and the first lower pattern BP1.

The substrate 100 may be bulk silicon or a silicon-on-insulator (SOI). Alternatively, the substrate 100 may be a silicon substrate, or may contain other materials such as silicon germanium (SiGe), silicon germanium on insulator (SGOI), indium antimonide, a lead tellurium compound, indium arsenide, indium phosphide, gallium arsenide, or gallium antimonide, but is not limited thereto. The upper surface of the substrate 100 may be formed into a flat surface parallel with the first direction (the X direction) and the second direction (the Y direction) intersecting the first direction (the X direction).

The substrate 100 may include the first well region PR having a first conductivity type and the second well region NR having a second conductivity type.

The first well region PR and the second well region NR may extend lengthwise in the second direction (the Y direction). The second well region NR may be positioned adjacent to the first well region PR in the first direction (the X direction). In the embodiment the second well region NR may refer to a well trench (NT) portion included in the substrate 100, doped with a first conductivity type impurity, and doped with a second conductivity type impurity. The second well region NR may be defined by the well trench NT of the substrate 100. The second well region NR may refer to a portion in the well trench NT where a material layer having the second conductivity type is positioned. For example, the first conductivity type impurity may contain B, V, In, Ga, Al, or a combination thereof, and the second conductivity type impurity may contain As, P, Sb, or a combination thereof. The following description will be made on the assumption that the first conductivity type is a p-type and the second conductivity type is an n-type. In other words, in the embodiment, the first well region PR may be an n-MOSFET region, and the second well region NR may be a p-MOSFET region.

On the substrate 100, the logic cells LC1 and LC2 and the tap cells TC1 and TC2 may be provided. For example, the first logic cell LC1 and the second tap cell TC2 may be provided in the first well region PR of the substrate 100, and the second logic cell LC2 and the first tap cell TC1 may be provided in the second well region NR of the substrate 100. The first logic cell LC1 may be an n-MOSFET, and the second logic cell LC2 may be a p-MOSFET. The first tap cell TC1 may be an element for applying the first power voltage VDD from the power transfer network to the second well region NR of the substrate 100, and the second tap cell TC2 may be an element for applying the second power voltage VSS from the power transfer network to the first well region PR of the substrate 100.

The lower patterns BP1 and BP2 may be positioned on the substrate 100. The lower patterns BP1 and BP2 may protrude from the substrate 100. The lower patterns BP1 and BP2 may extend lengthwise in the first direction (the X direction). The lower patterns BP1 and BP2 may protrude in a third direction (a Z direction) from the upper surface of the substrate 100. The lower patterns BP1 and BP2 may be positioned so as to be spaced apart from each other in the second direction (the Y direction).

The lower patterns BP1 and BP2 of the semiconductor device according to the embodiment may include the first lower pattern BP1 that is positioned in the first well region PR, and the second lower pattern BP2 that is positioned in the second well region NR.

The first lower pattern BP1 may protrude in the third direction (the Z direction) from the upper surface of the first well region PR of the substrate 100, and the second lower pattern BP2 may protrude in the third direction (the Z direction) from the upper surface of the second well region NR of the substrate 100. The first lower pattern BP1 may have the first conductivity type, and the second lower pattern BP2 may have the second conductivity type. In other words, the first lower pattern BP1 may have the same conductivity type as that of the first well region PR, and the second lower pattern BP2 may have the same conductivity type as that of the second well region NR. As an example, the first lower pattern BP1 may be a p-type, and the second lower pattern BP2 may be an n-type, but the present disclosure is not limited thereto.

In the embodiment, the first lower pattern BP1 may refer to lower patterns that are positioned in the first well region PR, and the second lower pattern BP2 may refer to lower patterns that are positioned in the second well region NR. The first lower pattern BP1 may be positioned in a region where an n-MOSFET is formed, and the second lower pattern BP2 may be positioned in a region where a p-MOSFET is formed.

The lower patterns BP1 and BP2 may be patterns formed by etching some portions of the substrate 100, and may include an epitaxial layer grown from the substrate 100. The lower patterns BP1 and BP2 may contain silicon (Si) or germanium (Ge) which is an elemental semiconductor material. Also, the lower patterns BP1 and BP2 may contain a compound semiconductor, and may be formed of or contain, for example, a IV-IV compound semiconductor or a III-V compound semiconductor.

The IV-IV compound semiconductor may be, for example, a binary compound, or a ternary compound containing at least two of carbon (C), silicon (Si), germanium (Ge), and tin (Sn).

The III-V compound semiconductor may be, for example, one of binary compounds, ternary compounds, and quaternary compounds which are formed by bonding of at least one of aluminum (Al), gallium (Ga), and indium (In) which are group III elements and one of phosphorus (P), arsenic (As), and antimony (Sb) which are group V elements.

The channel patterns NS1 and NS2 may be positioned on the upper surfaces of the lower patterns BP1 and BP2. The channel patterns NS1 and NS2 of the semiconductor device according to the embodiment may include a first channel pattern NS1 that is positioned in the first well region PR, and a second channel pattern NS2 that is positioned in the second well region NR.

The first channel pattern NS1 may be spaced apart from the first lower pattern BP1 in the third direction (the Z direction). On one first lower pattern BP1, first channel patterns NS1 may be positioned so as to be spaced apart from each other in the third direction (the Z direction). The second channel pattern NS2 may be spaced apart from the second lower pattern BP2 in the third direction (the Z direction). On one second lower pattern BP2, second channel patterns NS2 may be positioned so as to be spaced apart from each other in the third direction (the Z direction). Here, the third direction (the Z direction) may be a direction that intersects the first direction (the X direction) and the second direction (the Y direction). For example, the third direction (the Z direction) may be the thickness direction of the substrate 100. The second direction (the Y direction) may be a direction intersecting the first direction (the X direction). The first and second directions may be referred to as horizontal directions, and the third direction may be referred to as a vertical direction.

In the embodiment, the first channel pattern NS1 may refer to lower patterns that are positioned in the first well region PR, and the second channel pattern NS2 may refer to lower patterns that are positioned in the second well region NR.

Although it is shown in FIG. 3 that four first channel patterns NS1 and four second channel patterns NS2 are stacked in the third direction (the Z direction) so as to be spaced apart from each other, this is merely for ease of explanation, and the present disclosure is not limited thereto. For example, two or three first channel patterns NS1 and two or three second channel patterns NS2 are stacked in the third direction (the Z direction) so as to be spaced apart from each other, or five or more first channel patterns NS1 and five or more second channel patterns NS2 are stacked in the third direction (the Z direction) so as to be spaced apart from each other.

The channel patterns NS1 and NS2 may be formed of or contain one of silicon (Si) and silicon germanium (SiGe) which are elemental semiconductor materials, IV-IV compound semiconductors, and III-V compound semiconductors. In the embodiment, the channel patterns NS1 and NS2 may contain silicon (Si). In the semiconductor device according to the embodiment, the lower patterns BP1 and BP2 may be lower silicon patterns containing silicon (Si), and the channel patterns NS1 and NS2 may be silicon sheet patterns containing silicon (Si).

In the embodiment, the first channel pattern NS1 and the second channel pattern NS2 may contain the same material. The first channel pattern NS1 and the second channel pattern NS2 may not have the first conductivity type and/or the second conductivity type. In other words, the first channel pattern NS1 may be formed of a material different from that of the first lower pattern BP1, and the second channel pattern NS2 may be formed of a material different from the second lower pattern BP2. However, the present disclosure is not limited thereto, and for example, the first channel pattern NS1 and the second channel pattern NS2 may have the first conductivity type and/or the second conductivity type. As another example, the first channel pattern NS1 may have the first conductivity type, and the second channel pattern NS2 may have the second conductivity type. In other words, the first channel pattern NS1 may be formed of the same material as that of the first lower pattern BP1, and the second channel pattern NS2 may be formed of the same material as that of the second lower pattern BP2.

The semiconductor device according to the embodiment may further include a field insulating layer 105 that is positioned on the substrate 100.

The field insulating layer 105 may be positioned on the substrate 100. The field insulating layer 105 may be positioned on the side surfaces of the lower patterns BP1 and BP2. For example, the field insulating layer 105 may contact the side surfaces of the lower patterns BP1 and BP2. The field insulating layer 105 may not be positioned on the upper surfaces of the lower patterns BP1 and BP2. The field insulating layer 105 may cover some portions of the side surfaces of the lower patterns BP1 and BP2, but is not limited thereto. For example, the field insulating layer 105 may completely cover the side surfaces of the lower patterns BP1 and BP2. The individual channel patterns NS1 and NS2 may be positioned higher than the upper surface of the field insulating layer 105.

The field insulating layer 105 may contain various insulating materials. For example, the field insulating layer 105 may contain silicon oxide (SiO₂), but is not limited thereto. As another example, the field insulating layer 105 may include a silicon nitride (SiN) film, a silicon oxynitride (SiON) film, or a combination of silicon nitride films and silicon oxynitride films. In the drawings, the field insulating layer 105 is shown as a single layer, but this is merely for ease of explanation, and the present disclosure is not limited thereto.

Although it is shown as an example in FIG. 4 that the field insulating layer 105 is positioned on the side surface of the second lower pattern BP2, it goes without saying that the field insulating layer 105 may be positioned on the side surface of the first lower pattern BP1.

The gate structure GS may be positioned on the substrate 100. The gate structure GS may extend in the second direction (the Y direction). Gate structures GS may be arranged so as to be spaced apart in the first direction (the X direction).

The gate structures GS may be positioned on the lower patterns BP1 and BP2. The gate structures GS may cross the lower patterns BP1 and BP2 in a plan view. The gate structures GS may intersect the lower patterns BP1 and BP2 in a plan view. The gate structures GS may extend lengthwise in the second direction (the Y direction).

The gate structure GS may surround the individual channel patterns NS1 and NS2. For example, the gate structure GS may cover the side surfaces of the first channel pattern NS1 along the second direction (the Y direction), the lower surface and upper surface of the first channel pattern, the side surfaces of the second channel pattern NS2 along the second direction (the Y direction), and the lower surface and upper surface of the second channel pattern. The gate structure GS may completely surround four surfaces of each of the channel patterns NS1 and NS2. Accordingly, each of the side surfaces, lower surfaces, and upper surfaces of the channel patterns NS1 and NS2 may be in contact with the gate structure GS.

The gate structure GS may include a plurality of sub gate structures S_GS and a main gate structure M_GS. The plurality of sub gate structures S_GS may be positioned between first channel patterns NS1 adjacent in the third direction (the Z direction) and between the first lower pattern BP1 and the lowermost first channel pattern NS1. Also, the plurality of sub gate structures S_GS may be positioned between second channel patterns NS2 adjacent in the third direction (the Z direction) and between the second lower pattern BP2 and the lowermost second channel pattern NS2. The plurality of sub gate structures S_GS may be in contact with the source/drain patterns 150 and the well tap patterns 160 to be described below. The main gate structure M_GS may be positioned on the first channel pattern NS1 and the second channel pattern NS2 positioned at the top.

According to the embodiment, the number of sub gate structures S_GS may be proportional to the number of first channel patterns NS1 stacked in the third direction (the Z direction) and the number of second channel patterns NS2 stacked in the third direction (the Z direction). For example, the number of sub gate structures S_GS may be the same as the number of first channel patterns NS1 stacked in the third direction (the Z direction) and the number of second channel patterns NS2 stacked in the third direction (the Z direction). For example, as shown in FIG. 3, the number of sub gate structures S_GS may be four. However, the present disclosure is not limited thereto, and the plurality of sub gate structures S_GS may include three, or five or more sub gate structures S_GS.

The plurality of sub gate structures S_GS may include a sub gate electrode 120S, and a sub gate insulating layer 130S that surrounds the sub gate electrode 120S.

The sub gate electrode 120S may be positioned on the first lower pattern BP1 and the second lower pattern BP2. The sub gate electrode 120S may intersect the first lower pattern BP1 and the second lower pattern BP2. The sub gate electrode 120S may surround the first channel pattern NS1 and the second channel pattern NS2.

The sub gate electrode 120S may be formed of or contain at least one of metals, metal alloys, conductive metal nitrides, metal silicides, doped semiconductor materials, conductive metal oxides, and conductive metal oxynitrides. The sub gate electrode 120S may contain, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. The conductive metal oxides and the conductive metal oxynitrides may include the oxides of the above-mentioned materials, but are not limited thereto.

The sub gate insulating layer 130S may be positioned on the sub gate electrode 120S. The sub gate insulating layer 130S may surround and contact the sub gate electrode 120S. The sub gate insulating layer 130S may extend along the upper surface of each of the lower patterns BP1 and BP2. As shown in FIG. 3, in a cross-sectional view along the first direction (the X direction) and the third direction (the Z direction), the sub gate insulating layer 130S may surround the sub gate electrode 120S. The sub gate insulating layer 130S may be positioned between the sub gate electrode 120S and the source/drain pattern 150, and the sub gate insulating layer 130S may also be positioned between the sub gate electrode 120S and the channel patterns NS1 and NS2. The sub gate insulating layer 130S may be positioned between inner gate spacers 135 to be described below. The sub gate insulating layer 130S may be in contact with the side surfaces of the inner gate spacers 135 to be described below, but is not limited thereto. The sub gate insulating layer 130S may contain various insulating materials.

The sub gate insulating layer 130S is shown as a single layer in FIG. 3, but is not limited thereto, and the sub gate insulating layer 130S may consist of multiple layers made of insulating materials and high-dielectric constant materials. Here, the high-dielectric constant materials may include materials having dielectric constants greater than that of silicon oxide (SiO₂), such as hafnium oxide (HfO), aluminum oxide (AlO), or tantalum oxide (TaO).

The main gate structure M_GS may be positioned on the plurality of channel patterns NS1 and NS2. The main gate structure M_GS may be positioned on the upper surfaces of the plurality of channel patterns NS1 and NS2.

The main gate structure M_GS may include a main gate electrode 120M, and a main gate insulating layer 130M that surrounds at least a portion of the main gate electrode 120M.

The main gate electrode 120M may be positioned on the plurality of channel patterns NS1 and NS2. The main gate electrode 120M may be positioned on the upper surfaces of the plurality of channel patterns NS1 and NS2. The main gate electrode 120M may be positioned between gate spacers 142 to be described below. For example, the main gate electrode 120M may be positioned on the upper surfaces of the channel patterns NS1 and NS2 positioned at the top and the side surfaces of the gate spacers 142 to be described below.

The main gate electrode 120M may contain the same material as that of the sub gate electrode 120S. For example, the main gate electrode 120M may contain at least one of metals, metal alloys, conductive metal nitrides, metal silicides, doped semiconductor materials, conductive metal oxides, and conductive metal oxynitrides.

The main gate insulating layer 130M may be positioned on the lower surface of the main gate electrode 120M. The main gate insulating layer 130M may extend along the lower surface and side surfaces of the main gate electrode 120M. The main gate insulating layer 130M may extend along the side surfaces of the gate spacers 142 to be described below. In other words, the main gate insulating layer 130M may be positioned between the gate spacers 142 to be described below and the main gate electrode 120M and between the channel patterns NS1 and NS2 positioned at the top and the main gate electrode 120M.

The main gate insulating layer 130M may contain various insulating materials. The main gate insulating layer 130M may be integrally formed with the sub gate insulating layer 130S in the same process. The main gate insulating layer 130M may be integrally formed with the sub gate insulating layer 130S.

The main gate insulating layer 130M is shown as a single layer in FIG. 3, but is not limited thereto, and the main gate insulating layer 130M may consist of multiple layers made of insulating materials and high-dielectric constant materials. Here, the high-dielectric constant materials may include materials having dielectric constants greater than that of silicon oxide (SiO₂), such as hafnium oxide (HfO), aluminum oxide (AlO), or tantalum oxide (TaO).

The semiconductor device according to the embodiment may further include the inner gate spacers 135.

The inner gate spacers 135 may be positioned on the side surfaces of the sub gate structures S_GS. The inner gate spacers 135 may be positioned between the source/drain pattern 150 and the sub gate structures S_GS. For example, as shown in FIG. 3, the inner gate spacers 135 may be positioned on the side surfaces of the sub gate insulating layer 130S. The inner gate spacers 135 may be in contact with the side surfaces of the sub gate insulating layer 130S, but is not limited thereto. The inner gate spacers 135 may not be positioned on the side surfaces of the main gate structure M_GS. The inner gate spacers 135 may contain various insulating materials. For example, the inner gate spacers 135 may contain at least one of silicon oxide (SiO₂), silicon nitride (SiN), silicon oxynitride (SiON), and low-dielectric constant materials.

The semiconductor device according to the embodiment may further include the gate spacers 142.

The gate spacers 142 may be positioned on the side surfaces of the gate structure GS. For example, the gate spacers 142 may be positioned between the main gate structure M_GS and an interlayer insulating layer 190. The gate spacers 142 may not be positioned on the side surfaces of the plurality of sub gate structures S_GS.

The gate spacers 142 may contain various insulating materials. For example, the gate spacers 142 may contain silicon nitride (SiN). However, the gate spacers 142 are not limited thereto, and may contain at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof.

Although it is shown in FIG. 3 that each gate spacer 142 is formed of a single layer, the present disclosure is not limited thereto. For example, each gate spacer 142 may be formed of multiple layers.

The semiconductor device according to the embodiment may further include a capping layer 145 that is positioned on the gate structure GS.

The capping layer 145 may be positioned on the gate structure GS and the gate spacers 142. In an embodiment, the capping layer 145 may also be positioned on the side surfaces of the gate spacers 142 and the gate structure GS. The capping layer 145 may contain, for example, at least one of silicon nitride (SiN), silicon oxynitride (SiON), silicon carbonitride (SiCN), silicon oxycarbonitride (SiOCN), and combinations thereof. The capping layer 145 may contain a material having etch selectivity to the interlayer insulating layer 190.

The source/drain patterns 150 may be positioned on the lower patterns BP1 and BP2. For example, the source/drain patterns 150 may be positioned on the first lower pattern BP1 and the second lower pattern BP2. The source/drain patterns 150 may be positioned on opposite sides of the gate structure GS. For example, the source/drain patterns 150 may be positioned on opposite sides of the gate structure GS in the first direction (the X direction). Also, the source/drain patterns 150 may be positioned on opposite sides of the channel patterns NS1 and NS2 in the first direction (the X direction). The source/drain patterns 150 may be electrically connected to the channel patterns NS1 and NS2.

The source/drain patterns 150 of the semiconductor device according to the embodiment may include the first source/drain pattern 151 that is positioned on the first lower pattern BP1, and a second source/drain pattern 152 that is positioned on the second lower pattern BP2. Here, the first source/drain pattern 151 may refer to the source/drain pattern 150 that is positioned in the first logic cell LC1, and the second source/drain pattern 152 may refer to the source/drain pattern 150 that is positioned in the second logic cell LC2.

Referring to FIG. 5, the first source/drain pattern 151 may be positioned on the first lower pattern BP1. The first source/drain pattern 151 may be positioned in the first well region PR having the first conductivity type. The first source/drain pattern 151 may be positioned on the first barrier pattern 310 to be described below. The first source/drain pattern 151 may be spaced apart from the first lower pattern BP1, but is not limited thereto. The lower surface 151_B of the first source/drain pattern 151 may be in contact with the first barrier pattern 310 to be described below.

The first source/drain pattern 151 may be positioned inside a first source/drain recess 151R having a depth in the third direction (the Z direction). The first source/drain pattern 151 may fill at least a portion of the first source/drain recess 151R. For example, the first source/drain pattern 151 may fill a portion of the first source/drain recess 151R that remains after the first barrier pattern 310 to be described below is formed. The bottom surface of the first source/drain recess 151R may be defined by the first lower pattern BP1. The side surfaces of the first source/drain recess 151R may be defined by the inner gate spacers 135 and the first channel pattern NS1. However, the present disclosure is not limited thereto, and a semiconductor device according to some embodiments may include no inner gate spacers, and in this case, the side surfaces of the first source/drain recess 151R may be defined by the first channel pattern NS1 and the gate structure GS.

The outer surfaces of the first source/drain pattern 151 may be in contact with the first channel pattern NS1 and the inner gate spacers 135. The outer surface of the first source/drain pattern 151 may consist of an uneven curved surface. For example, the portion of the outer surface of the first source/drain pattern 151 in contact with the first channel pattern NS1 may have a concave or approximately flat shape in a cross-sectional view, but is not limited thereto. This is because after the first source/drain recess 151R is formed, when a process of selectively etching a dummy gate structure is further performed, the first source/drain recess 151R may be formed in an uneven shape.

The first source/drain pattern 151 may be epitaxial patterns formed by a selective epitaxial growth process using the first channel pattern NS1 as a seed. The first source/drain pattern 151 may have the second conductivity type. The second conductivity type may be an n-type. The first source/drain pattern 151 may be doped with a second conductivity type impurity. For example, the second conductivity type impurity may contain As, P, Sb, or a combination thereof. The first source/drain pattern 151 may serve as the source/drain of the first logic cell LC1 using the first channel pattern NS1 as a channel region.

The first source/drain pattern 151 of the semiconductor device according to the embodiment may include a first source/drain layer 151a that is positioned on the first barrier pattern 310 to be described below, and a second source/drain layer 151b that is positioned on the first source/drain layer 151a.

The first source/drain layer 151a may be positioned on the first barrier pattern 310. The first source/drain layer 151a may contact the first barrier pattern 310. The first source/drain layer 151a may be formed along the inner walls of the first source/drain recess 151R. In other words, the first source/drain layer 151a may be positioned on opposite sides of the gate structure GS in the first direction (the X direction). The first source/drain layer 151a may be positioned on opposite sides of the first channel pattern NS1 in the first direction X. The first source/drain layer 151a may be in direct contact with the side surfaces of the first channel pattern NS1. Also, the first source/drain layer 151a may be in contact with the side surfaces of the inner gate spacers 135, but is not limited thereto. The portions of the first source/drain layer 151a in contact with the inner gate spacers 135 may have curved portions, but are not limited thereto.

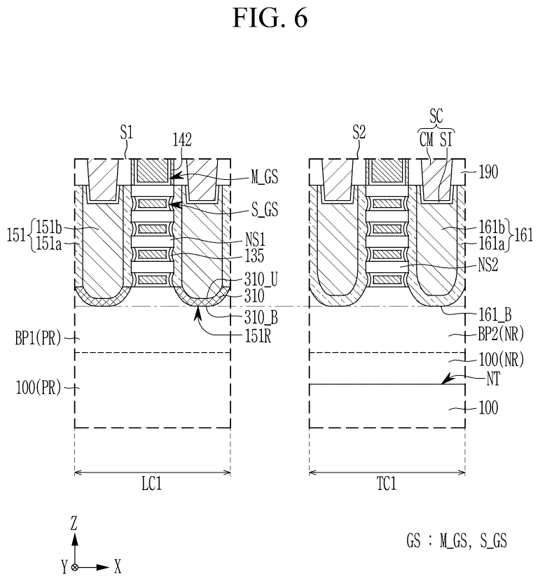

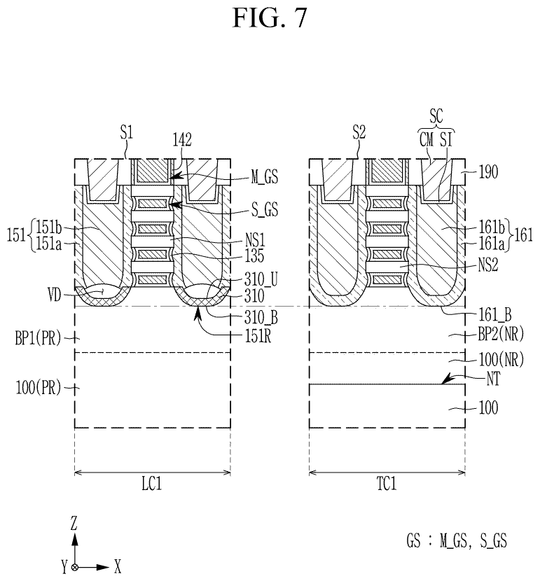

In the embodiment, the first source/drain layer 151a may be a pattern formed by epitaxial growth using the first channel pattern NS1 and the first barrier pattern 310 as a seed. However, the present disclosure is not limited thereto, and the first source/drain layer 151a may use the first channel pattern NS1 as a seed but may not use the first barrier pattern 310 as a seed. In this case, the first source/drain layer 151a may not be positioned on at least a portion of the first barrier pattern 310. This will be described below with reference to FIGS. 6 and 7.

The first source/drain layer 151a may contain a semiconductor material. For example, the first source/drain layer 151a may contain silicon (Si). The first source/drain layer 151a may be doped with a second conductivity type impurity, but is not limited thereto. The second conductivity type may be an n-type. For example, the first source/drain layer 151a may contain As, P, Sb, or a combination thereof.

The second source/drain layer 151b may be positioned on opposite sides of the first channel pattern NS1 in the first direction (the X direction). The second source/drain layer 151b may be positioned on opposite sides of the gate structure GS in the first direction (the X direction). The second source/drain layer 151b may fill a portion of the first source/drain recess 151R that remains after the first source/drain layer 151a is formed. The second source/drain layer 151b may cover opposite side surfaces and lower surface of the first source/drain layer 151a, but is not limited thereto. The second source/drain layer 151b may contact the first source/drain layer 151a.

The second source/drain layer 151b may contain a semiconductor material. The second source/drain layer 151b may contain the same material as that of the first source/drain layer 151a. For example, the second source/drain layer 151b may contain silicon (Si). The second source/drain layer 151b may be doped with a second conductivity type impurity, but is not limited thereto. The second conductivity type may be an n-type. For example, the second source/drain layer 151b may contain As, P, Sb, or a combination thereof.

In this case, the concentration of the impurity implanted into the first source/drain layer 151a may be different from the concentration of the impurity implanted into the second source/drain layer 151b. For example, the concentration of the second conductivity type impurity implanted into the second source/drain layer 151b may be higher than the concentration of the second conductivity type impurity implanted into the first source/drain layer 151a, but is not limited thereto. However, the present disclosure is not limited thereto, and as another example, the second source/drain layer 151b and the first source/drain layer 151a may further contain carbon C, tin (Sn), or a combination thereof. As a further example, the second source/drain layer 151b may contain the same material as that of the first source/drain layer 151a, and the second source/drain layer 151b and the first source/drain layer 151a may have the same concentration of constituent material.

Although it has been described in the embodiment that the first source/drain pattern 151 consists of double layers, the present disclosure is not limited thereto, and the first source/drain pattern 151 may consist of a single layer or three or more layers containing a semiconductor material.

Referring to FIG. 3 again, the second source/drain pattern 152 may be positioned on the second lower pattern BP2. The second source/drain pattern 152 may be positioned in the second well region NR having the second conductivity type. The second source/drain pattern 152 may be positioned on opposite sides of the second channel pattern NS2. In the embodiment, the second source/drain pattern 152 may be positioned between the first source/drain pattern 151 and a first well tap pattern 161. The lower surface of the second source/drain pattern 152 may be in contact with the second lower pattern BP2.

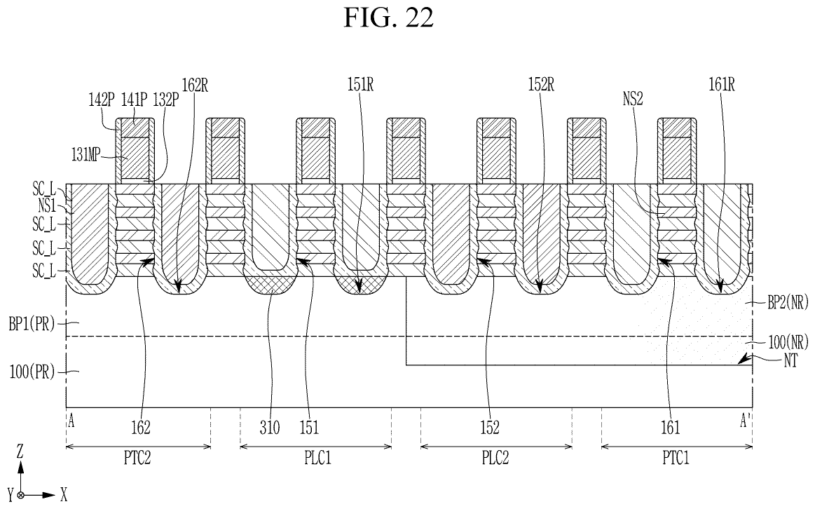

The second source/drain pattern 152 may be positioned inside a second source/drain recess (reference symbol “152R” in FIG. 22) having a depth in the third direction (the Z direction). The second source/drain pattern 152 may completely fill the second source/drain recess (reference symbol “152R” in FIG. 22). In this case, the depth of the second source/drain recess (reference symbol “152R” in FIG. 22) in the third direction (the Z direction) may be substantially the same as the depth of the first source/drain recess 151R in the third direction (the Z direction); however, the present disclosure is not limited thereto.

In the embodiment, a portion of the second source/drain pattern 152 may be electrically connected to the first source/drain pattern 151, and the other portion may be electrically connected to the first well tap pattern 161 to be described below. For example, a portion of the second source/drain pattern 152 may be electrically connected to the first source/drain pattern 151 through a fourth contact electrode SC4. The other portion of the second source/drain pattern 152 may be electrically connected to the first well tap pattern 161 through a fifth contact electrode SC5.

The second source/drain pattern 152 may be epitaxial patterns formed by a selective epitaxial growth process using the second channel pattern NS2 and the second lower pattern BP2 as a seed.

The second source/drain pattern 152 may have the first conductivity type. The second source/drain pattern 152 may be doped with a first conductivity type impurity. The first conductivity type may be a p-type. For example, the first conductivity type impurity may contain B, V, In, Ga, Al, or a combination thereof. The second source/drain pattern 152 may serve as the source/drain of the second logic cell LC2 using the second channel pattern NS2 as a channel region.

In the embodiment, the first source/drain pattern 151 and the gate structure GS may constitute the first logic cell LC1 which is a second conductivity type transistor using the first channel pattern NS1 as a channel region, and the second source/drain pattern 152 and the gate structure GS may constitute the second logic cell LC2 which is a first conductivity type transistor using the second channel pattern NS2 as a channel region.

The well tap patterns 160 may be positioned on the lower patterns BP1 and BP2. For example, the well tap patterns 160 may be positioned on the first lower pattern BP1 and the second lower pattern BP2. The well tap patterns 160 may be positioned on opposite sides of the gate structure GS. For example, the well tap patterns 160 may be positioned on opposite sides of the gate structure GS in the first direction (the X direction). Also, the well tap patterns 160 may be positioned on opposite sides of the channel patterns NS1 and NS2 in the first direction (the X direction). The well tap patterns 160 may be electrically connected to the channel patterns NS1 and NS2.

The well tap patterns 160 of the semiconductor device according to the embodiment may include the first well tap pattern 161 that is positioned on the second lower pattern BP2, and a second well tap pattern 162 that is positioned on the first lower pattern BP1. Here, the first well tap pattern 161 may refer to the well tap pattern 160 positioned in the first tap cell TC1, and the second well tap pattern 162 may refer to the well tap pattern 160 positioned in the second tap cell TC2.

Referring to FIG. 5, the first well tap pattern 161 may be positioned on the second lower pattern BP2. The first well tap pattern 161 may be positioned in the second well region NR having the second conductivity type. The lower surface 161_B of the first well tap pattern 161 may be in contact with the second lower pattern BP2. The first well tap pattern 161 may not be positioned on the first barrier pattern 310 to be described below, but is not limited thereto. The first well tap pattern 161 may be positioned on opposite sides of the second channel pattern NS2. The first well tap pattern 161 may be positioned on opposite sides of the gate structure GS positioned in the first tap cell TC1.

The first well tap pattern 161 may be positioned inside a first well tap recess 161R having a depth in the third direction (the Z direction). The first well tap pattern 161 may fill the first well tap recess 161R. The bottom surface of the first well tap recess 161R may be defined by the second lower pattern BP2. The side surface of the first well tap recess 161R may be defined by the inner gate spacers 135 and the second channel pattern NS2. However, the present disclosure is not limited thereto, and a semiconductor device according to some embodiments may not include any inner gate spacer, and in this case, the side surface of the first well tap recess 161R may be defined by the second channel pattern NS2 and the gate structure GS.

In the embodiment, the depth of the first well tap recess 161R in the third direction (the Z direction) may be substantially the same as the depth of the first source/drain recess 151R in the third direction (the Z direction). In other words, the bottom surface of the first well tap recess 161R may be positioned substantially at the same level as that of the bottom surface of the first source/drain recess 151R. The bottom surface of the first well tap recess 161R and the bottom surface of the first source/drain recess 151R may be positioned substantially at the same distance from the lower surface of the substrate 100.

Accordingly, the thickness of the first well tap pattern 161 in the third direction (the Z direction) may be larger than the thickness of the first source/drain pattern 151 in the third direction (the Z direction). Here, the thickness of the first well tap pattern 161 in the third direction (the Z direction) may refer to the maximum thickness of the first well tap pattern 161 in the third direction (the Z direction). The first well tap pattern 161 may protrude from the lower surface GS_B of the gate structure GS toward the substrate 100 in the third direction (the Z direction). For example, the upper surface of the first well tap pattern 161 may be positioned substantially at the same level as that of the upper surface of the first source/drain pattern 151, and the lower surface 161_B of the first well tap pattern 161 may be positioned at a level lower than that of the lower surface 151_B of the first source/drain pattern 151. In other words, the lower surface 161_B of the first well tap pattern 161 may be positioned closer to the lower surface of the substrate 100 than the lower surface 151_B of the first source/drain pattern 151. This is because the first well tap recess 161R and the first source/drain recess 151R have the same depth and the first barrier pattern 310 is positioned inside the first source/drain recess 151R.

In the embodiment, the thickness of the first well tap pattern 161 in the third direction (the Z direction) may be substantially the same as the thickness of the second source/drain pattern 152 in the third direction (the Z direction). For example, the upper surface of the first well tap pattern 161 may be positioned at the same level as that of the upper surface of the second source/drain pattern 152, and the lower surface 161_B of the first well tap pattern 161 may be positioned substantially at the same level as that of the lower surface of the second source/drain pattern 152. In other words, the lower surface 161_B of the first well tap pattern 161 and the lower surface of the second source/drain pattern 152 may be positioned substantially at the same distance from the lower surface of the substrate 100.

In the embodiment, since the first well tap pattern 161 may protrude from the lower surface GS_B of the gate structure GS toward the substrate 100 in the third direction (the Z direction), and the lower surface 161_B of the first well tap pattern 161 may be in contact with the second lower pattern BP2, the contact area between the first well tap pattern 161 and the second lower pattern BP2 can be sufficiently secured. As an example, the contact area between the first well tap pattern 161 and the second lower pattern BP2 may be larger than the contact area between the first source/drain pattern 151 and the first lower pattern BP1.

The outer surface of the first well tap pattern 161 may be in contact with the second channel pattern NS2 and the inner gate spacers 135. The outer surface of the first well tap pattern 161 may have substantially the same shape as that of the outer surface of the first source/drain pattern 151. The outer surface of the first well tap pattern 161 may consist of an uneven curved surface. For example, the portion of the outer surface of the first well tap pattern 161 in contact with the second channel pattern NS2 may have a concave or approximately flat shape in a cross-sectional view, but are not limited thereto. However, the present disclosure is not limited thereto, and as another example, the outer surface of the first well tap pattern 161 may be flat.

The first well tap pattern 161 may be epitaxial patterns formed by a selective epitaxial growth process using the second lower pattern BP2 and the second channel pattern NS2 as a seed.

The first well tap pattern 161 may contain the same material as that of the first source/drain pattern 151. The first well tap pattern 161 may have the same conductivity type as that of the first source/drain pattern 151. The first well tap pattern 161 may have the second conductivity type. The second conductivity type may be an n-type. The first well tap pattern 161 may be doped with a second conductivity type impurity. For example, the second conductivity type impurity may contain As, P, Sb, or a combination thereof. The first well tap pattern 161 may provide an electrical connection path for applying the first power voltage VDD from the power transfer network to the inside the second well region NR of the substrate 100.

The first well tap pattern 161 of the semiconductor device according to the embodiment may include a first well tap layer 161a that is positioned on the second lower pattern BP2, and a second well tap layer 161b that is positioned on the first well tap layer 161a.

The first well tap layer 161a may be positioned on the second lower pattern BP2. The first well tap layer 161a may contact the second lower pattern BP2. The first well tap layer 161a may be formed along the bottom surface and inner walls of the first well tap recess 161R. In other words, the first well tap layer 161a may be positioned on the upper surface of the second lower pattern BP2 and opposite sides of the gate structure GS in the first direction (the X direction). The first well tap layer 161a may be positioned on opposite sides of the second channel pattern NS2 in the first direction (the X direction). The first well tap layer 161a may be in direct contact with the side surfaces of the second channel pattern NS2. Also, the first well tap layer 161a may be in contact with the side surfaces of the inner gate spacers 135, but is not limited thereto. The portions of the first well tap layer 161a in contact with the inner gate spacers 135 may have curved portions, but are not limited thereto.

The first well tap layer 161a may contain a semiconductor material. The first well tap layer 161a may contain the same material as that of the first source/drain layer 151a. For example, the first well tap layer 161a may contain silicon (Si). The first well tap layer 161a may be doped with a second conductivity type impurity, but is not limited thereto. The second conductivity type may be an n-type. For example, the first well tap layer 161a may contain As, P, Sb, or a combination thereof.

The second well tap layer 161b may be positioned on opposite sides of the first channel pattern NS1 in the first direction (the X direction). The second well tap layer 161b may be positioned on opposite sides of the gate structure GS in the first direction (the X direction). The second well tap layer 161b may fill a portion of the first well tap recess 161R that remains after the first well tap layer 161a is formed. The second well tap layer 161b may contact the first well tap layer 161a.

The second well tap layer 161b may contain a semiconductor material. The second well tap layer 161b may contain the same material as that of the second source/drain layer 151b. For example, the second well tap layer 161b may contain silicon (Si). The second well tap layer 161b may be doped with a second conductivity type impurity, but is not limited thereto. The second conductivity type may be an n-type. For example, the second well tap layer 161b may contain As, P, Sb, or a combination thereof.

In this case, the concentration of the impurity implanted into the first well tap layer 161a may be different from the concentration of the impurity implanted into the second well tap layer 161b. For example, the concentration of the second conductivity type impurity implanted into the second well tap layer 161b may be higher than the concentration of the second conductivity type impurity implanted into the first well tap layer 161a, but is not limited thereto. However, the present disclosure is not limited thereto, and as another example, the second well tap layer 161b and the first well tap layer 161a may further contain carbon C, tin (Sn), or a combination thereof. As a further example, the second well tap layer 161b may contain the same material as that of the first well tap layer 161a, and the second well tap layer 161b and the first well tap layer 161a may have the same concentration of constituent material.

Although it has been described in the embodiment that the first well tap pattern 161 consists of double layers, the present disclosure is not limited thereto, and the first well tap pattern 161 may consist of a single layer or three or more layers containing a semiconductor material.

The second well tap pattern 162 may be positioned on the first lower pattern BP1. The second well tap pattern 162 may be positioned on the first well region PR having the first conductivity type. The lower surface of the second well tap pattern 162 may be in contact with the first lower pattern BP1.

The second well tap pattern 162 may contain the same material as that of the second source/drain pattern 152. The second well tap pattern 162 may have the first conductivity type. The second well tap pattern 162 may be doped with a first conductivity type impurity. The first conductivity type may be a p-type. For example, the first conductivity type impurity may contain B, V, In, Ga, Al, or a combination thereof. The second well tap pattern 162 may provide an electrical connection path for applying the second power voltage VSS from the power transfer network to the inside of the first well region PR of the substrate 100.

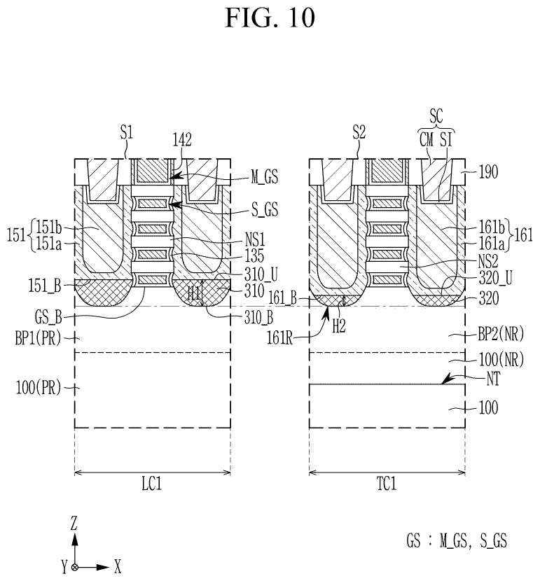

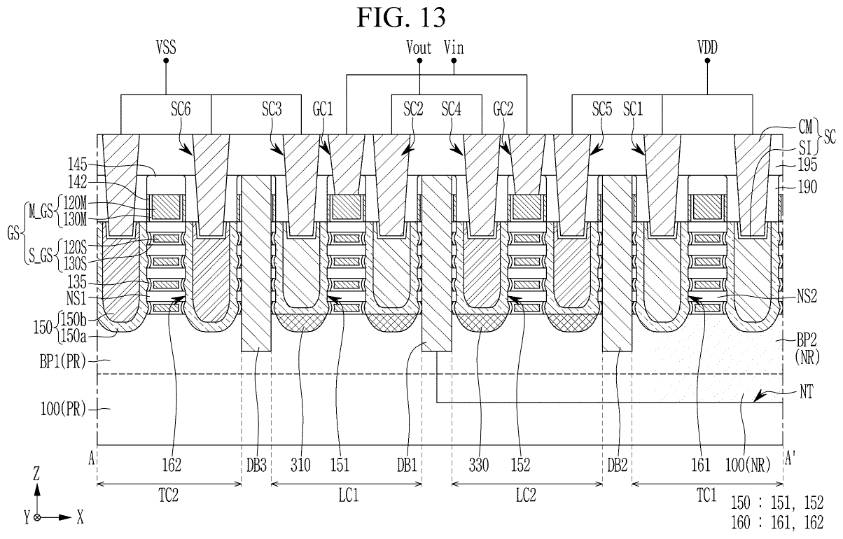

The first barrier pattern 310 may be positioned between the first source/drain pattern 151 and the first lower pattern BP1. The first barrier pattern 310 may be positioned on the first lower pattern BP1. Unlike this, the first barrier pattern 310 may not be positioned on the second lower pattern BP2, but the present disclosure is not limited thereto. For example, the first barrier pattern 310 may not be positioned between the well tap pattern 160 and the second lower pattern BP2. Also, any barrier pattern may not be positioned between the second source/drain pattern 152 and the second lower pattern BP2, but the present disclosure is not limited thereto. For example, a second barrier pattern (see, e.g., second barrier pattern 330 in FIG. 13) may be positioned between the second source/drain pattern 152 and the second lower pattern BP2. This will be described below in detail with reference to FIGS. 10 to 12.

The first barrier pattern 310 may be positioned inside the first source/drain recess 151R having a depth in the third direction (the Z direction). The first barrier pattern 310 may fill at least a portion of the first source/drain recess 151R, and the first source/drain pattern 151 may fill the other portion of the first source/drain recess 151R. This may be due to the process characteristic in which after the first source/drain recess 151R is formed, inside the first source/drain recess 151R, the first barrier pattern 310 is first formed and the first source/drain pattern 151 is formed.

The first barrier pattern 310 may include a lower surface 310_B and an upper surface 310_U. The lower surface 310_B of the first barrier pattern 310 may be defined as the bottom surface of the first source/drain recess 151R. In other words, the lower surface 310_B of the first barrier pattern 310 may be defined by the first lower pattern BP1. The upper surface 310_U of the first barrier pattern 310 may be defined as the lower surface 151_B of the first source/drain pattern 151.

The lower surface 310_B of the first barrier pattern 310 may be in contact with the first lower pattern BP1. The lower surface 310_B of the first barrier pattern 310 may be positioned substantially at the same level as that of the lower surface 161_B of the first well tap pattern 161. In other words, the lower surface 310_B of the first barrier pattern 310 and the lower surface 161_B of the first well tap pattern 161 may be positioned substantially at the same distance from the lower surface of the substrate 100. This may be due to the process characteristic in which the depth of the first source/drain recess 151R in the third direction (the Z direction) and the depth of the first well tap recess 161R in the third direction (the Z direction) are substantially the same. However, the present disclosure is not limited thereto, and the lower surface 310_B of the first barrier pattern 310 may be positioned at a level different from that of the lower surface 161_B of the first well tap pattern 161. This will be described below with reference to FIGS. 10 to 12.

The upper surface 310_U of the first barrier pattern 310 may be in contact with the first source/drain pattern 151. The upper surface 310_U of the first barrier pattern 310 may be in contact with the first source/drain layer 151a and second source/drain layer 151b of the first source/drain pattern 151, but is not limited thereto. The upper surface 310_U of the first barrier pattern 310 may be positioned at a level higher than that of the lower surface 161_B of the first well tap pattern 161. The upper surface 310_U of the first barrier pattern 310 may be positioned substantially at the same level as that of the lower surface GS_B of the gate structure GS. In other words, the upper surface 310_U of the first barrier pattern 310 and the lower surface GS_B of the gate structure GS may be substantially at the same distance from the lower surface of the substrate 100. Here, the lower surface GS_B of the gate structure GS may refer to the lower surface of the gate structure GS which is in contact with the first lower pattern BP1. Accordingly, the first source/drain pattern 151 may be spaced apart from the first lower pattern BP1, but is not limited thereto. However, the present disclosure is not limited thereto, and the upper surface 310_U of the first barrier pattern 310 may be positioned at a level different from that of the lower surface GS_B of the gate structure GS.

The upper surface 310_U of the first barrier pattern 310 may be flat, but is not limited thereto. For example, the upper surface 310_U of the first barrier pattern 310 may be convex or concave in a direction away from the lower surface of the substrate 100.

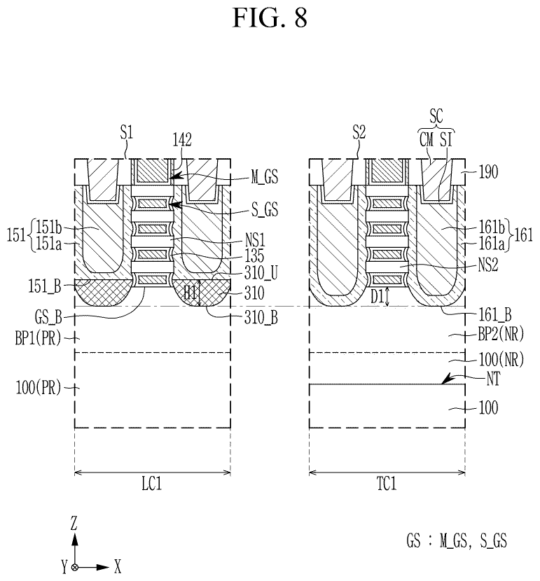

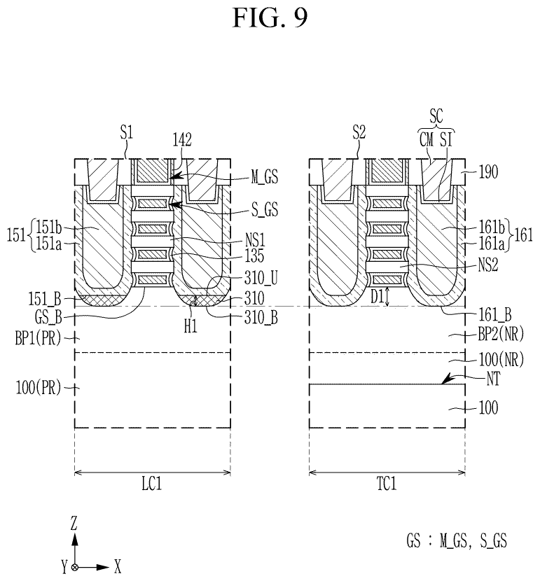

The first thickness H1 of the first barrier pattern 310 in the third direction (the Z direction) may be substantially the same as the first distance D1 between the lower surface GS_B of the gate structure GS and the lower surface 161_B of the first well tap pattern 161 in the third direction (the Z direction). This may be due to the process characteristic in which the first barrier pattern 310 and the first source/drain pattern 151 are sequentially formed inside the first source/drain recess 151R having the same depth in the third direction (the Z direction) as that of the first well tap recess 161R. However, the present disclosure is not limited thereto, and the first thickness H1 of the first barrier pattern 310 in the third direction (the Z direction) may be different from the first distance D1 between the lower surface GS_B of the gate structure GS and the lower surface 161_B of the first well tap pattern 161 in the third direction (the Z direction). This will be described below with reference to FIGS. 8 and 9.

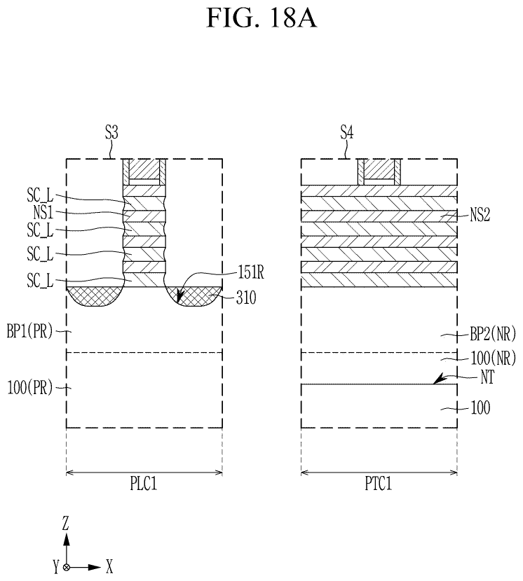

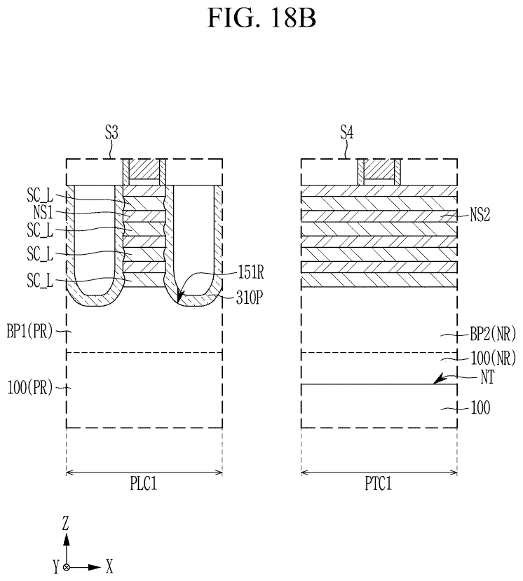

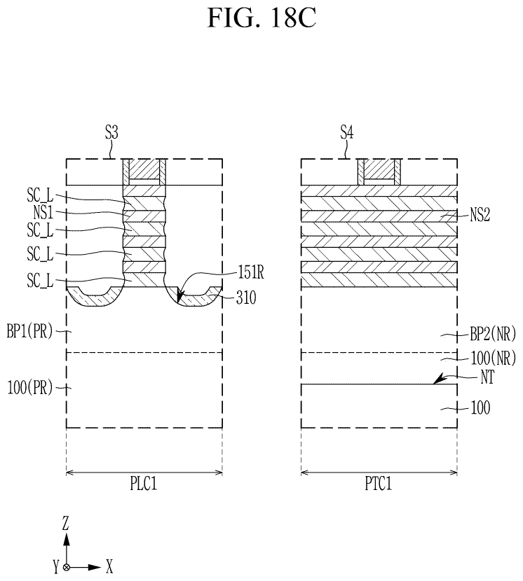

The first barrier pattern 310 may contain various insulating materials. For example, the first barrier pattern 310 may contain silicon boride (SiB). As another example, the first barrier pattern 310 may contain at least one of silicon oxide (SiO₂), silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof. In the embodiment, the first barrier pattern 310 may be formed using an epitaxial growth method using the first lower pattern BP1 as a seed. However, the present disclosure is not limited thereto, and the first barrier pattern may be formed by depositing a first barrier pattern material layer (see e.g., first barrier pattern material layer 310P in FIG. 18B) inside the first source/drain recess 151R and removing at least a portion of the first barrier pattern material layer by wet etching or the like.

The substrate 100 of the semiconductor device according to the embodiment may include the first well region PR having the first conductivity type and the second well region NR having the second conductivity type, and the first logic cell LC1 consisting of a second conductivity type transistor may be positioned in the first well region PR, and the second logic cell LC2 consisting of a first conductivity type transistor may be positioned in the second well region NR. Further, the first tap cell TC1 having the second conductivity type may be positioned in the second well region NR, and the second tap cell TC2 having the first conductivity type may be positioned in the first well region PR. In the semiconductor device having this structure, a parasitic bipolar transistor (e.g., a parasitic NPN transistor or a parasitic PNP transistor) may operate sometimes. This may cause parasitic current, which may act as noise to the logic cells LC1 and LC2 and may cause latch-up. In this case, the leakage current characteristic of the source/drain pattern 150 may be improved or the resistance of the tap cells TC1 and TC2 may be reduced to prevent a latch-up phenomenon.

As the first barrier pattern 310 of the semiconductor device according to the embodiment is positioned between the first source/drain pattern 151 and the first lower pattern BP1, leakage current flowing from the first source/drain pattern 151 of the first logic cell LC1 into the first lower pattern BP1 and/or the substrate 100 can be prevented from occurring. Accordingly, electrons generated by leakage current can be prevented from being injected from the first well region PR into the second well region NR, and a latch-up phenomenon of the semiconductor device according to the embodiment can be prevented.

Meanwhile, the first barrier pattern 310 of the semiconductor device according to the embodiment may not be positioned between the first well tap pattern 161 and the second lower pattern BP2. Accordingly, a sufficient contact area can be secured between the first well tap pattern 161 and the second lower pattern BP2, and the contact resistance between the first well tap pattern 161 and the second lower pattern BP2 can decrease. Therefore, the potential of the first power voltage VDD applied to the inside of the substrate 100 through the first tap cell TC1 can be maintained, and a latch-up phenomenon of the semiconductor device according to the embodiment can be prevented.

The semiconductor device according to the embodiment may further include the isolation structures DB1, DB2, and DB3.

The isolation structures DB1, DB2, and DB3 may be positioned between the logic cells LC1 and LC2 and the tap cells TC1 and TC2. In other words, the logic cells LC1 and LC2 and the tap cells TC1 and TC2 may be isolated by the isolation structures DB1, DB2, and DB3. By the isolation structures DB1, DB2, and DB3, the logic cells LC1 and LC2 and the tap cells TC1 and TC2 may be defined. For example, the first isolation structure DB1 may be positioned between the first logic cell LC1 and the second logic cell LC2, the second isolation structure DB2 may be positioned between the second logic cell LC2 and the first tap cell TC1, and the third isolation structure DB3 may be positioned between the first logic cell LC1 and the second tap cell TC2; however, the present disclosure is not limited thereto. Lower surfaces of the isolation structures DB1, DB2, and DB3 may be lower than lowermost surfaces of the source/drain patterns 150, the well tap patterns 160, and first barrier patterns 310.

The isolation structures DB1, DB2, and DB3 may pass through the capping layer 145 and the gate structure GS. By the isolation structures DB1, DB2, and DB3, the first source/drain pattern 151 and the second source/drain pattern 152, the second source/drain pattern 152 and the first well tap pattern 161, and the first source/drain pattern 151 and the second well tap pattern 162 may be electrically isolated. The isolation structures DB1, DB2, and DB3 may contain various insulating materials.

The semiconductor device according to the embodiment may further include the interlayer insulating layer 190. The interlayer insulating layer 190 may be positioned on the source/drain pattern 150. The interlayer insulating layer 190 may not cover the upper surface of the gate structure GS. The interlayer insulating layer 190 may be positioned between the side surfaces of gate structures GS. The interlayer insulating layer 190 may surround the source/drain pattern 150. The interlayer insulating layer 190 may contact side surfaces of the first to sixth contact electrodes SC1 to SC6. The interlayer insulating layer 190 may contact upper surfaces of the source/drain patterns 150 and upper surfaces of the well tap patterns 160.

The interlayer insulating layer 190 may contain, for example, at least one of silicon oxide (SiO₂), silicon nitride (SiN), silicon oxynitride (SiON), and low-dielectric constant materials. The low-dielectric constant materials may contain, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or combinations thereof, but are not limited thereto.

An etch stop film, which is positioned between the interlayer insulating layer 190 and the source/drain patterns 150 and between the interlayer insulating layer 190 and the gate spacers 142 in the semiconductor device according to the embodiment, may be further included.

The etch stop film may be positioned on the side surfaces of the gate spacers 142 and the upper surfaces of the source/drain patterns 150. Also, the etch stop film may surround at least a portion of the source/drain patterns 150. The etch stop film may contain a material having etch selectivity to the interlayer insulating layer 190. Also, the etch stop film may contain a material having etch selectivity to the source/drain patterns 150 to be described below. The etch stop film may contain, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

The semiconductor device according to the embodiment may further include an upper insulating layer 195. The upper insulating layer 195 may be positioned on the upper surface of the interlayer insulating layer 190 and the upper surface of the capping layer 145.

The semiconductor device according to the embodiment may further include contact electrodes SC and gate contact electrodes GC.

The contact electrodes SC may be positioned on the source/drain pattern 150 and the well tap pattern 160. The contact electrode SC may pass through the upper insulating layer 195 and the interlayer insulating layer 190 and be electrically connected to the source/drain patterns 150 and the well tap patterns 160. A plurality of contact electrodes SC may be provided and be electrically connected to any one of the source/drain patterns 150 and the well tap patterns 160. The plurality of contact electrodes SC may include first to sixth contact electrodes SC1 to SC6. For example, a first contact electrode SC1 may be electrically connected to the first well tap pattern 161, and a second contact electrode SC2 and a third contact electrode SC3 may be electrically connected to the first source/drain pattern 151. A fourth contact electrode SC4 and a fifth contact electrode SC5 may be electrically connected to the second source/drain pattern 152, and a sixth contact electrode SC6 may be electrically connected to the second well tap pattern 162.

At least a portion of each of the plurality of contact electrodes SC may be positioned inside the source/drain patterns 150 and the well tap patterns 160. At least a portion of each of the plurality of contact electrodes SC may be surrounded by the source/drain patterns 150 and the well tap patterns 160. The lower surfaces of the contact electrodes SC may be positioned at a level lower than that of the upper surfaces of the source/drain patterns 150 and the upper surface of the well tap patterns 160.

In the embodiment, the contact electrodes SC may be electrically connected to the power transfer network. Accordingly, a signal having a predetermined voltage may be applied from the power transfer network to the source/drain patterns 150 and the well tap patterns 160 through the contact electrodes SC. For example, the first power voltage VDD may be applied to the first well tap pattern 161 through the first contact electrode SC1. The second power voltage VSS may be applied to the second well tap pattern 162 through the sixth contact electrode SC6. Accordingly, the first power voltage VDD and the second power voltage VSS may be applied to the substrate 100 through the well tap patterns 160. Here, the second power voltage VSS may be a ground voltage, and the magnitude of the first power voltage VDD may be larger than the magnitude of the second power voltage VSS. Further, the first power voltage VDD may be applied to the second source/drain pattern 152 of the second logic cell LC2 through the fifth contact electrode SC5. The second power voltage VSS may be applied to the first source/drain pattern 151 of the first logic cell LC1 through the third contact electrode SC3. Accordingly, the first power voltage VDD and the second power voltage VSS may be applied to the logic cells LC1 and LC2.

In the embodiment, the contact electrodes SC may be electrically connected to an external wiring line for applying an output voltage Vout. The output voltage Vout may be applied to the second source/drain pattern 152 of the second logic cell LC2 through the fourth contact electrode SC4, and applied to the first source/drain pattern 151 of the first logic cell LC1 through the second contact electrode SC2. Accordingly, the output voltage Vout may be applied to the logic cells LC1 and LC2.

The contact electrodes SC each may include a conductive pattern CM and a silicide pattern SI that surrounds the conductive pattern CM. The conductive pattern CM may contain a conductive material. The conductive pattern CM may contain, for example, at least one of metals, metal alloys, conductive metal nitrides, conductive metal carbides, conductive metal oxides, conductive metal carbonitrides, and two-dimensional (2D) materials. The silicide pattern SI may cover the lower surface and side surfaces of the conductive pattern CM. The silicide pattern SI may include at least one metal silicide film.

The gate contact electrode GC may be positioned on the gate structure GS. The gate contact electrode GC may pass through the upper insulating layer 195 and the capping layer 145 and be electrically connected to the gate structure GS. A plurality of gate contact electrodes GC may be provided and electrically connected to the gate structures GS of the logic cells LC1 and LC2. For example, a first gate contact electrode GC1 may be electrically connected to the gate structure GS of the first logic cell LC1, and a second gate contact electrode GC2 may be electrically connected to the gate structure GS of the second logic cell LC2.

In the embodiment, the gate contact electrodes GC may be electrically connected to an external wiring line for applying an input voltage Vin. Here, the input voltage Vin may be a gate signal for turning on the logic cells LC1 and LC2. The input voltage Vin may be applied to the gate structure GS of the first logic cell LC1 through the first gate contact electrode GC1. The input voltage Vin may be applied to the gate structure GS of the second logic cell LC2 through the second gate contact electrode GC2. In other words, the input voltage Vin may be applied to the gate structures GS of the logic cells LC1 and LC2 such that the logic cells LC1 and LC2 of the semiconductor device according to the embodiment are turned on.

The gate contact electrode GC may contain a conductive material. The gate contact electrode GC may contain, for example, at least one of metals, metal alloys, conductive metal nitrides, conductive metal carbides, conductive metal oxides, conductive metal carbonitrides, and two-dimensional (2D) materials.

The connection relationship of the input voltage Vin, the output voltage Vout, the first power voltage VDD, and the second power voltage with the logic cells LC1 and LC2 and the tap cells TC1 and TC2 is merely an example, and the present disclosure is not limited thereto.

Hereinafter, a semiconductor device according to some example embodiments will be described with reference to FIGS. 6 to 9.

FIGS. 6 to 9 are cross-sectional views illustrating a semiconductor device according to some example embodiments and corresponding to the region S1 and the region S2 of FIG. 3.

The embodiments shown in FIGS. 6 to 9 have much in common with the embodiment shown in FIGS. 1 to 5, and thus will be described with a focus on the differences without repeating descriptions. In the embodiment of FIGS. 6 to 9, the first barrier pattern 310 may have various shapes.

Referring to FIG. 6, the first barrier pattern 310 of the semiconductor device according to some embodiments may have a shape that is concave toward the substrate 100. The first barrier pattern 310 may be positioned with a uniform thickness along the bottom surface and inner walls of the first source/drain recess 151R. The lower surface 310_B and upper surface 310_U of the first barrier pattern 310 may include curved surfaces concave toward the substrate 100. In this case, the thickness of the first barrier pattern 310 may be different from the first distance D1 between the lower surface GS_B of the gate structure GS and the lower surface 161_B of the first well tap pattern 161. For example, the thickness of the first barrier pattern 310 may be smaller than the first distance D1 between the lower surface GS_B of the gate structure GS and the lower surface 161_B of the first well tap pattern 161 in the third direction (the Z direction).

In some embodiments, the first source/drain layer 151a of the first source/drain pattern 151 may be a pattern formed by epitaxial growth using the first channel pattern NS1 as a seed. In this case, the first source/drain layer 151a may not use the first barrier pattern 310 as a seed. Accordingly, at least a portion of the upper surface 310_U of the first barrier pattern 310 may not be in contact with the first source/drain layer 151a.

In the embodiment of FIG. 6, the first barrier pattern 310 may be formed by depositing a first barrier pattern material layer (reference symbol “310P” in FIG. 18B) inside the first source/drain recess 151R and removing at least a portion of the first barrier pattern material layer (see e.g., first barrier pattern material layer 310P in FIG. 18B) by wet etching or the like.

Referring to FIG. 7, the semiconductor device according to some embodiments may further include a void VD which is positioned between the first barrier pattern 310 and the first source/drain pattern 151. The void VD may be defined by the upper surface 310_U of the first barrier pattern 310 and the lower surface of the first source/drain pattern 151. The void VD may be positioned so as to be spaced apart from the first lower pattern BP1. The void VD may be positioned so as to be spaced apart from the gate structure GS and the first channel pattern NS1 in a horizontal direction (for example, the first direction (the X direction) and/or the second direction (the Y direction)). The void VD may be due to the epitaxial growth process characteristic in which in the process of forming the first source/drain pattern 151 by an epitaxial growth method after forming the first barrier pattern 310 inside the first source/drain recess 151R, the first barrier pattern 310 is not used as a seed or the growth rate from the first barrier pattern 310 is significantly lower than the growth rate from the first channel pattern NS1. The void VD may be filled with air. The term “air” as discussed herein, may refer to atmospheric air, or other gases that may be present during the manufacturing process.

Referring to FIG. 8, the first barrier pattern 310 of the semiconductor device according to some embodiments may overlap the gate structure GS in the horizontal direction (for example, the first direction (the X direction) and/or the second direction (the Y direction)).

In some embodiments, the upper surface 310_U of the first barrier pattern 310 may be positioned at a level higher than that of the lower surface GS_B of the gate structure GS. In other words, the upper surface 310_U of the first barrier pattern 310 may be positioned farther from the lower surface of the substrate 100 than the lower surface GS_B of the gate structure GS. Accordingly, the first barrier pattern 310 may be in contact with the gate structure GS. The first thickness H1 of the first barrier pattern 310 in the third direction (the Z direction) may be larger than the first distance D1 between the lower surface GS_B of the gate structure GS and the lower surface 161_B of the first well tap pattern 161 in the third direction (the Z direction). The first thickness H1 of the first barrier pattern 310 in the third direction (the Z direction) may be a maximum thickness, and the first distance D1 between the lower surface GS_B of the gate structure GS and the lower surface 161_B of the first well tap pattern 161 in the third direction (the Z direction) may be a maximum distance.

Referring to FIG. 9, at least a portion of the first source/drain pattern 151 of the semiconductor device according to some embodiments may be in contact with the first lower pattern BP1. In some embodiments, the lower surface 151_B of the first source/drain pattern 151 may be positioned at a level lower than that of the lower surface GS_B of the gate structure GS. In other words, the lower surface 151_B of the first source/drain pattern 151 may be positioned closer to the lower surface of the substrate 100 than the lower surface GS_B of the gate structure GS. Accordingly, a portion of the side surfaces of the first source/drain pattern 151 may be in contact with the first lower pattern BP1.

In some embodiments, the upper surface 310_U of the first barrier pattern 310 may be positioned at a level lower than that of the lower surface GS_B of the gate structure GS. In other words, the upper surface 310_U of the first barrier pattern 310 may be positioned closer to the lower surface of the substrate 100 than the lower surface GS_B of the gate structure GS. Accordingly, the first thickness H1 of the first barrier pattern 310 in the third direction (the Z direction) may be smaller than the first distance D1 between the lower surface GS_B of the gate structure GS and the lower surface 161_B of the first well tap pattern 161 in the third direction (the Z direction).

Even in the case of the embodiment of FIG. 9, as the first barrier pattern 310 is positioned between the first source/drain pattern 151 and the first lower pattern BP1, the contact area between the first source/drain pattern 151 and the first lower pattern BP1 may decrease, and accordingly, leakage current flowing from the first source/drain pattern 151 of the first logic cell LC1 into the first lower pattern BP1 and/or the substrate 100 can be prevented from occurring.

Hereinafter, a semiconductor device according to some embodiments will be described with reference to FIGS. 10 to 12.

FIGS. 10 to 12 are cross-sectional views illustrating a semiconductor device according to some example embodiments and corresponding to the region S1 and the region S2 of FIG. 3.

The embodiments shown in FIGS. 10 to 12 have much in common with the embodiment shown in FIGS. 1 to 5, and thus will be described with a focus on the differences without repeating descriptions. In the embodiment of FIGS. 10 to 12, a dummy barrier pattern 320 which is positioned between the second lower pattern BP2 and the first well tap pattern 161 may be further included.

Referring to FIG. 10, the dummy barrier pattern 320 may be positioned between the second lower pattern BP2 and the first well tap pattern 161. The dummy barrier pattern 320 may be positioned inside the first well tap recess 161R. The lower surface of the dummy barrier pattern 320 may be positioned substantially at the same level as that of the lower surface of the first barrier pattern 310. In other words, the lower surface of the dummy barrier pattern 320 and the lower surface of the first barrier pattern 310 may be positioned substantially at the same distance from the lower surface of the substrate 100. The upper surface 320_U of the dummy barrier pattern 320 may be in contact with the lower surface 161_B of the first well tap pattern 161. The upper surface 320_U of the dummy barrier pattern 320 may be positioned closer to the lower surface of the substrate 100 than the upper surface 310_U of the first barrier pattern 310. Each of the upper surface 320_U of the dummy barrier pattern 320 and the upper surface 310_U of the first barrier pattern 310 may be substantially planar. In some embodiments, the second thickness H2 of the dummy barrier pattern 320 in the third direction (the Z direction) may be smaller than the first thickness H1 of the first barrier pattern 310 in the third direction (the Z direction), but is not limited thereto. Each of the first thickness H1 of the first barrier pattern 310 and the second thickness H2 of the dummy barrier pattern 320 may be a maximum thickness. Accordingly, the first well tap pattern 161 may be in contact with the second lower pattern BP2.

The dummy barrier pattern 320 may contain various insulating materials. The dummy barrier pattern 320 may contain the same material as that of the first barrier pattern 310. For example, the dummy barrier pattern 320 may contain silicon boride (SiB). As another example, the dummy barrier pattern 320 may contain at least one of silicon oxide (SiO₂), silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

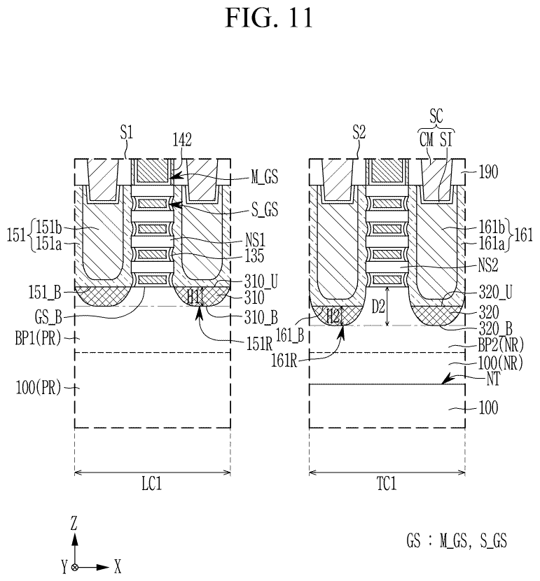

Referring to FIG. 11, the depth in the third direction (the Z direction) of the first well tap recess 161R of the semiconductor device according to some embodiments may be deeper than the depth of the first source/drain recess 151R in the third direction (the Z direction).

In this case, the second thickness H2 of the dummy barrier pattern 320 in the third direction (the Z direction) may be substantially the same as the first thickness H1 of the first barrier pattern 310 in the third direction (the Z direction), but is not limited thereto. The second thickness H2 of the dummy barrier pattern 320 in the third direction (the Z direction) may be smaller than the second distance D2 between the lower surface GS_B of the gate structure GS and a level of the lower surface 320_B of the dummy barrier pattern 320 in the third direction (the Z direction). This may be due to the process characteristic in which the dummy barrier pattern 320 and the first barrier pattern 310 are simultaneously formed inside the first well tap recess 161R and the first source/drain recess 151R. Accordingly, the lower surface 320_B of the dummy barrier pattern 320 may be positioned closer to the lower surface of the substrate 100 than the lower surface 310_B of the first barrier pattern 310. The upper surface 320_U of the dummy barrier pattern 320 may be positioned closer to the lower surface of the substrate 100 than the upper surface 310_U of the first barrier pattern 310. Further, the lower surface 161_B of the first well tap pattern 161 may be positioned closer to the lower surface of the substrate 100 than the lower surface 151_B of the first source/drain pattern 151. Each of the first thickness H1 of the first barrier pattern 310 and the second thickness H2 of the dummy barrier pattern 320 may be a maximum thickness, and the second distance D2 between the lower surface GS_B of the gate structure GS and a level of the lower surface 320_B of the dummy barrier pattern 320 in the third direction (the Z direction) may be a maximum distance.

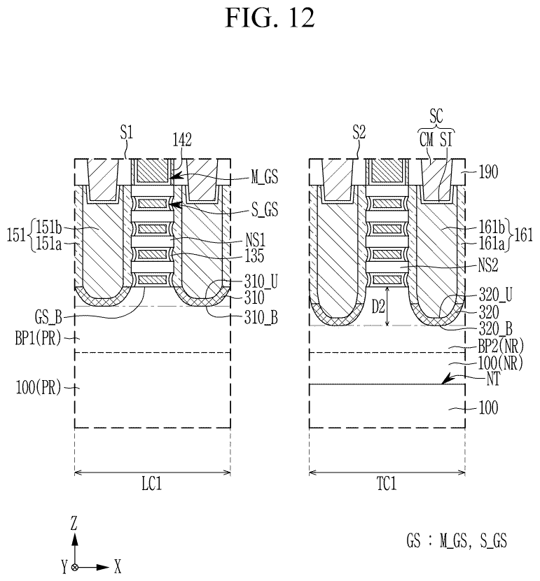

Referring to FIG. 12, the dummy barrier pattern 320 may be concave toward the substrate 100. The dummy barrier pattern 320 may be positioned with a uniform thickness along the bottom surface and inner walls of the first well tap recess 161R. The lower surface 320_B and upper surface 320_U of the dummy barrier pattern 320 may include curved surfaces concave toward the substrate 100.

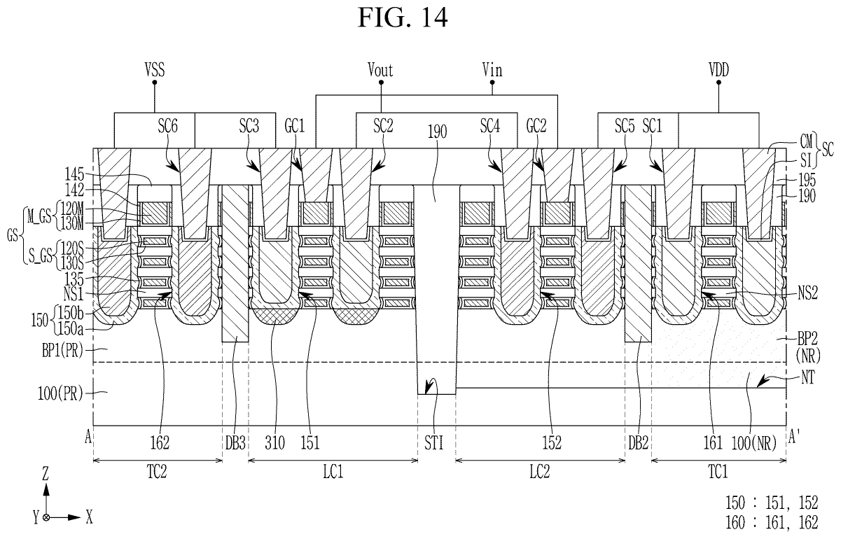

Hereinafter, a semiconductor device according to some embodiments will be described with reference to FIGS. 13 and 14.

FIGS. 13 and 14 are cross-sectional views illustrating a semiconductor device according to some embodiments and corresponding to line A-A′ of FIG. 1.

The embodiments shown in FIGS. 13 and 14 have much in common with the embodiment shown in FIGS. 1 to 5, and thus will be described with a focus on the differences without repeating descriptions.

Referring to FIG. 13, the semiconductor device according to some embodiments may further include a second barrier pattern 330 which is positioned between the second source/drain pattern 152 and the second lower pattern BP2.

The second barrier pattern 330 may be positioned between the second source/drain pattern 152 and the second lower pattern BP2. The second barrier pattern 330 may be positioned on the second lower pattern BP2. In some embodiments, the second barrier pattern 330 may not be positioned between the first lower pattern BP1 and the second well tap pattern 162, but is not limited thereto.

The second barrier pattern 330 may be positioned inside the second source/drain recess having a depth in the third direction (the Z direction). The second barrier pattern 330 may fill at least a portion of the second source/drain recess, and the second source/drain pattern 152 may fill the other portion of the second source/drain recess. The second barrier pattern 330 may contain the same material as that of the first barrier pattern 310, but is not limited thereto, and the second barrier pattern 330 may contain a material different from that of the first barrier pattern 310.

In some embodiments, the lower surface of the second barrier pattern 330 may be positioned substantially at the same level as that of the lower surface of the first well tap pattern 161. In other words, the lower surface of the second barrier pattern 330 and the lower surface of the first well tap pattern 161 may be positioned substantially at the same distance from the lower surface of the substrate 100. The arrangement relationship of the second barrier pattern 330, the second source/drain pattern 152, and the second lower pattern BP2 is substantially the same as the arrangement relationship of the first barrier pattern 310, the first source/drain pattern 151, and the first lower pattern BP1, and thus will not be made.

Referring to FIG. 14, at least some of the logic cells LC1 and LC2 and the tap cells TC1 and TC2 of the semiconductor device according to some embodiments may be isolated by a substrate trench STI. For example, the first source/drain pattern 151 and the second source/drain pattern 152 may be isolated from each other by the substrate trench STI. By the substrate trench STI, the first source/drain pattern 151 and the second source/drain pattern 152 may be electrically isolated. The substrate trench STI may pass through the lower patterns BP1 and BP2. Inside the substrate trench STI, the interlayer insulating layer 190 may be positioned.

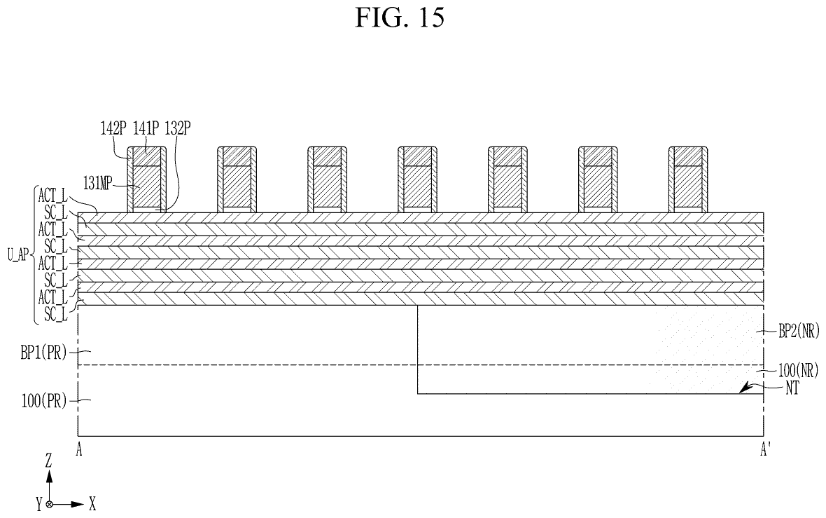

Hereinafter, a method of manufacturing the semiconductor device according to the example embodiment will be described with reference to FIGS. 15 to 26.

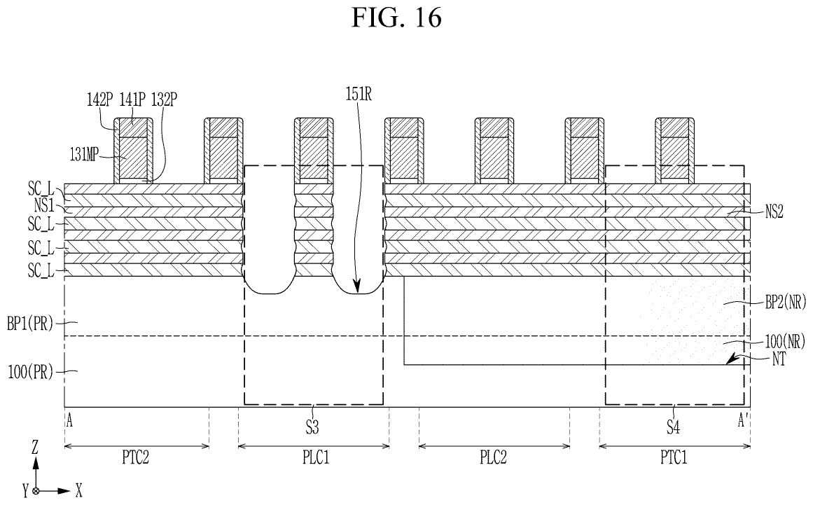

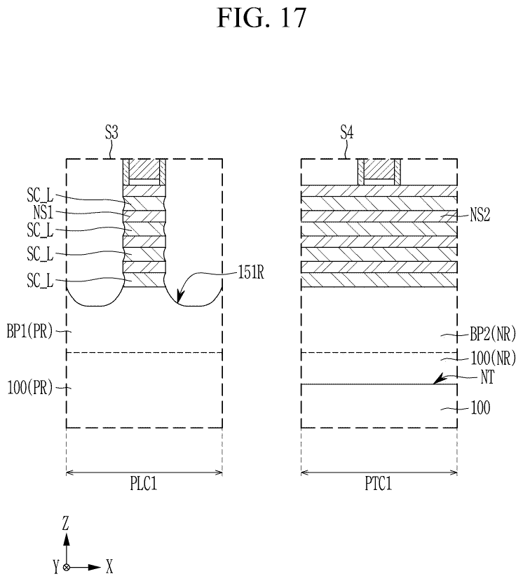

FIGS. 15 to 26 are cross-sectional views illustrating processes of an intermediate stage of a method of manufacturing the semiconductor device according to the embodiment. Specifically, FIG. 15, FIG. 16, and FIGS. 22 to 26 are cross-sectional views illustrating the method of manufacturing the semiconductor device according to the embodiment and corresponding to line A-A′ of FIG. 1. FIGS. 17 to 21C are cross-sectional views illustrating the method of manufacturing the semiconductor device according to the embodiment and corresponding to the region S1 and the region S2 of FIG. 3.

As shown in FIG. 15, an upper pattern structure U_AP is formed on the substrate 100, and a preliminary gate insulating film 132P, a preliminary main gate electrode 131MP, preliminary gate spacers 142P, and a preliminary capping layer 141P are formed.

First, on the substrate 100, the upper pattern structure U_AP is formed. The substrate 100 may be a silicon-on-insulator (SOI) or bulk silicon. Alternatively, the substrate 100 may be a silicon substrate, or may contain other materials such as silicon germanium (SiGe), silicon germanium on insulator (SGOI), indium antimonide, a lead tellurium compound, indium arsenide, indium phosphide, gallium arsenide, or gallium antimonide, but is not limited thereto.

The substrate 100 may include the first well region PR having the first conductivity type and the second well region NR having the second conductivity type.

The first well region PR and the second well region NR may extend in the second direction (the Y direction). The second well region NR may be positioned adjacent to the first well region PR in the first direction (the X direction). In the embodiment, the second well region NR may refer to a well trench (NT) portion included in the substrate 100, doped with a first conductivity type impurity, and doped with a second conductivity type impurity. The second well region NR may be defined by the well trench NT of the substrate 100. The second well region NR may refer to a portion in the well trench NT where a material layer having the second conductivity type is positioned. For example, the first conductivity type impurity may contain B, V, In, Ga, Al, or a combination thereof, and the second conductivity type impurity may contain As, P, Sb, or a combination thereof. The following description will be made on the assumption that the first conductivity type is a p-type and the second conductivity type is an n-type. In other words, in the embodiment, the first well region PR may be an n-MOSFET region, and the second well region NR may be a p-MOSFET region.

The upper pattern structure U_AP may be positioned on the substrate 100. The upper pattern structure U_AP may include sacrifice patterns SC_L and active patterns ACT_L alternately stacked on the substrate 100. For example, the sacrifice patterns SC_L may contain silicon germanium (SiGe). The active patterns ACT_L may contain silicon (Si).

Subsequently, on the upper pattern structure U_AP, the preliminary gate insulating film 132P, the preliminary main gate electrode 131MP, the preliminary gate spacers 142P, and the preliminary capping layer 141P are formed. On opposite side surfaces of the preliminary main gate electrode 131MP, the preliminary gate spacers 142P may be formed. The preliminary gate insulating film 132P may contain, for example, silicon oxide (SiO₂), but is not limited thereto. The preliminary main gate electrode 131MP may contain, for example, polysilicon, but is not limited thereto. The preliminary capping layer 141P and the preliminary gate spacers 142P may contain, for example, silicon nitride, but are not limited thereto.

As shown in FIGS. 16 and 17, the first source/drain recess 151R may be formed by etching at least some portions of the upper pattern structure U_AP and the substrate 100.

The semiconductor device according to the embodiment may include a first logic cell formation region PLC1, a second logic cell formation region PLC2, a first tap cell formation region PTC1, and a second tap cell formation region PTC2. The first logic cell formation region PLC1 may refer to a region where the first logic cell (see, e.g., first logic cell LC1 in FIG. 1) is formed, the second logic cell formation region PLC2 may refer to a region where the second logic cell (see, e.g., second logic cell LC2 in FIG. 1) is formed, the first tap cell formation region PTC1 may refer to a region where the first tap cell (see, e.g., first tap cell TC1 in FIG. 1) is formed, and the second tap cell formation region PTC2 may refer to a region where the second tap cell (see, e.g., second tap cell TC2 in FIG. 1) is formed.

In the first logic cell formation region PLC1, the first source/drain recess 151R may be formed by etching at least some portions of the upper pattern structure U_AP and the substrate 100 using the preliminary main gate electrode 131MP and the preliminary gate spacers 142P as a mask. The first source/drain recess 151R may pass through the upper pattern structure U_AP. The first source/drain recess 151R may pass through at least a portion of the substrate 100. In other words, a portion of the first source/drain recess 151R may be formed inside the substrate 100.

As the active patterns ACT_L are divided when the first source/drain recess 151R is formed, the plurality of channel patterns NS1 and NS2 may be formed. The plurality of channel patterns NS1 and NS2 may be positioned on opposite sides of the first source/drain recess 151R. The plurality of channel patterns NS1 and NS2 and the sacrifice pattern SC_L may have a structure in which they are alternately stacked. In this case, the lengths of the plurality of individual channel patterns NS1 and NS2 may be different or the same.

As shown in FIGS. 18A to 18C, the first barrier pattern 310 may be formed inside first source/drain recess 151R.

The first barrier pattern 310 may be formed in the first well region PR of the substrate 100. The first barrier pattern 310 may be formed on the first lower pattern BP1. The first barrier pattern 310 may fill a portion of the first source/drain recess 151R. The upper surface of the first barrier pattern 310 and the lower surface of the lowermost sacrifice pattern SC_L may be positioned substantially at the same boundary. The upper surface of the first barrier pattern 310 and the lower surface of the lowermost sacrifice pattern SC_L may be positioned substantially at the same distance from the lower surface of the substrate 100. In the embodiment, as shown in FIG. 18A, the first barrier pattern 310 may be formed by an epitaxial growth method using the first lower pattern BP1 as a seed. As another example, the first barrier pattern 310 may be formed by depositing the first barrier pattern material layer 310P along the inner walls and bottom surface of the first source/drain recess 151R as shown in FIG. 18B, and then removing at least a portion of the first barrier pattern material layer 310P as shown in FIG. 18C by performing an etching process. In this case, the process of removing at least a portion of the first barrier pattern material layer 310P may be performed using a wet etching process, but is not limited thereto.

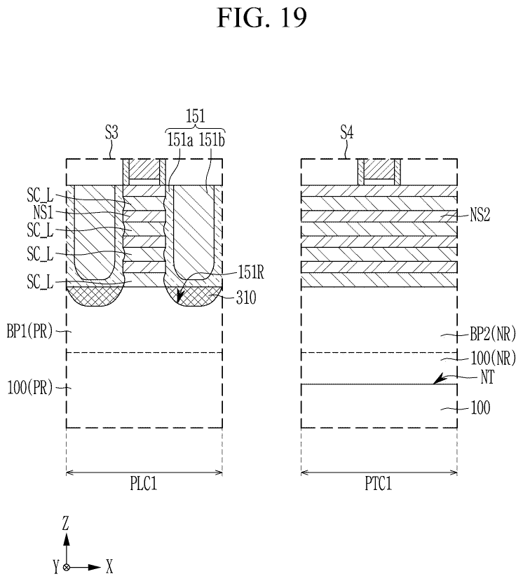

As shown in FIG. 19, the first source/drain pattern 151 is formed inside the first source/drain recess 151R.

First, the first source/drain pattern 151 is formed inside the first source/drain recess 151R. The first source/drain pattern 151 may be formed on the first barrier pattern 310. The first source/drain pattern 151 may be formed by an epitaxial growth method using the first channel pattern NS1 and the first barrier pattern 310 as a seed. Specifically, the first source/drain layer 151a may be formed along the side walls of the first source/drain recess 151R and the upper surface of the first barrier pattern 310. However, the present disclosure is not limited thereto, and the first source/drain layer 151a may be formed only on the side walls of the first source/drain recess 151R. Subsequently, the second source/drain layer 151b may be formed on the first source/drain layer 151a. The second source/drain layer 151b may fill the first source/drain recess 151R.

The first source/drain pattern 151 may have the second conductivity type. The second conductivity type may be an n-type. The first source/drain pattern 151 may be doped with a second conductivity type impurity. For example, the second conductivity type impurity may contain As, P, Sb, or a combination thereof.

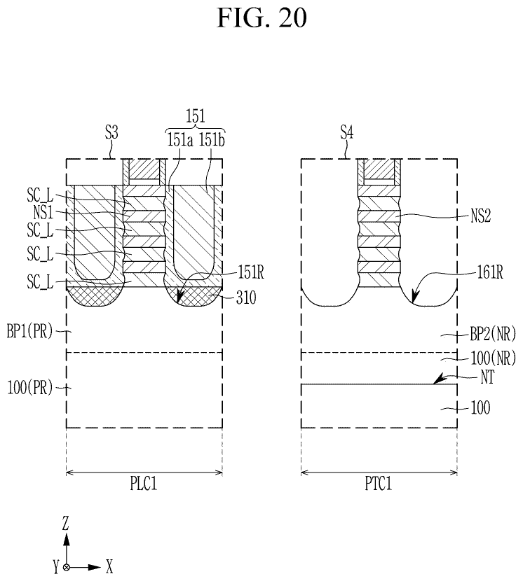

As shown in FIG. 20, in the first tap cell formation region PTC1, the first well tap recess 161R may be formed by etching at least some portions of the upper pattern structure U_AP and the substrate 100 using the preliminary main gate electrode 131MP and the preliminary gate spacers 142P as a mask. The first well tap recess 161R may pass through the upper pattern structure U_AP. The first well tap recess 161R may pass through at least a portion of the substrate 100. In other words, a portion of the first well tap recess 161R may be formed inside the substrate 100.

In the embodiment, the depth of the first well tap recess 161R in the third direction (the Z direction) may be substantially the same as the depth of the first source/drain recess 151R in the third direction (the Z direction). In other words, the bottom surface of the first well tap recess 161R and the bottom surface of the first source/drain recess 151R may be positioned substantially at the same level. The bottom surface of the first well tap recess 161R and the bottom surface of the first source/drain recess 151R may be positioned substantially at the same distance from the lower surface of the substrate 100 in the third direction (the Z direction).

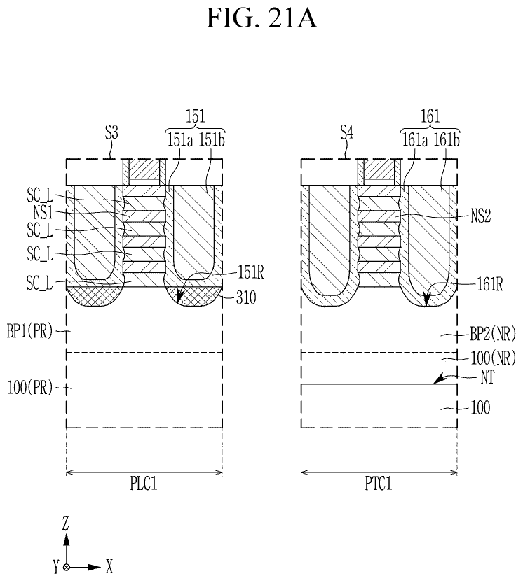

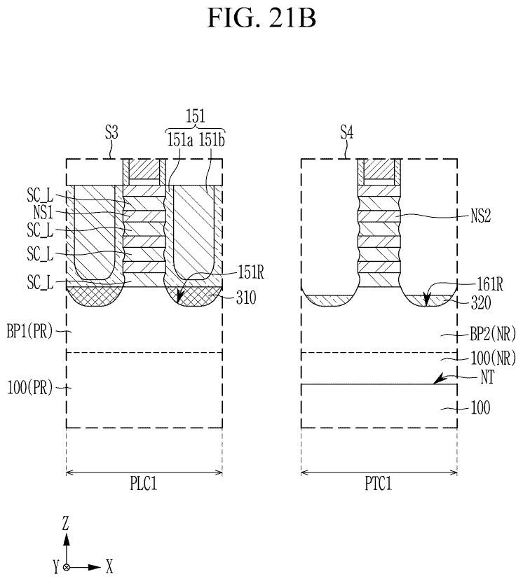

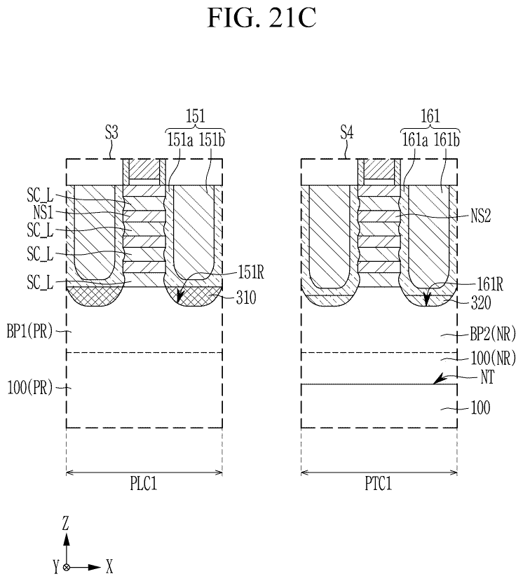

As shown in FIG. 21A, the first well tap pattern 161 may be formed inside the first well tap recess 161R. The first well tap pattern 161 may contain the same material as that of the first source/drain pattern 151. The first well tap pattern 161 may have the same conductivity type as that of the first source/drain pattern 151. The first well tap pattern 161 may have the second conductivity type. The second conductivity type may be an n-type. The first well tap pattern 161 may be doped with a second conductivity type impurity. For example, the second conductivity type impurity may contain As, P, Sb, or a combination thereof. The first well tap pattern 161 may provide an electrical connection path for applying the first power voltage VDD from the power transfer network to the inside the second well region NR of the substrate 100.

The first well tap pattern 161 may be formed by an epitaxial growth method using the second channel pattern NS2 and the second lower pattern BP2 as a seed. Specifically, the first well tap layer 161a may be formed along the side walls and bottom surface of the first well tap recess 161R. Subsequently, the second well tap layer 161b may be formed on the first well tap layer 161a. The second well tap layer 161b may fill the first well tap recess 161R.

However, the present disclosure is not limited thereto, and as another example, after the dummy barrier pattern 320 is formed inside the first well tap recess 161R as shown in FIG. 21B, the second well tap layer may be formed as shown in FIG. 21C by an epitaxial growth method using the second channel pattern NS2 and the dummy barrier pattern 320 as a seed.

The first well tap layer 161a may contain a semiconductor material. The first well tap layer 161a may contain the same material as that of the first source/drain layer 151a. For example, the first well tap layer 161a may contain silicon (Si). The first well tap layer 161a may be doped with a second conductivity type impurity, but is not limited thereto. The second conductivity type may be an n-type. For example, the first well tap layer 161a may contain As, P, Sb, or a combination thereof. The second well tap layer 161b may contain a semiconductor material. The second well tap layer 161b may contain the same material as that of the second source/drain layer 151b. For example, the second well tap layer 161b may contain silicon (Si). The second well tap layer 161b may be doped with a second conductivity type impurity, but is not limited thereto. The second conductivity type may be an n-type. For example, the second well tap layer 161b may contain As, P, Sb, or a combination thereof.

In the embodiment, the thickness of the first well tap pattern 161 in the third direction (the Z direction) may be larger than the thickness of the first source/drain pattern 151 in the third direction (the Z direction). Here, the thickness of the first well tap pattern 161 in the third direction (the Z direction) may refer to the maximum thickness of the first well tap pattern 161 in the third direction (the Z direction). The first well tap pattern 161 may protrude from the lower surface GS_B of the gate structure GS toward the substrate 100 in the third direction (the Z direction). For example, the upper surface of the first well tap pattern 161 may be positioned substantially at the same level as that of the upper surface of the first source/drain pattern 151, and the lower surface 161_B of the first well tap pattern 161 may be positioned at a level lower than that of the lower surface 151_B of the first source/drain pattern 151. In other words, the lower surface 161_B of the first well tap pattern 161 may be positioned closer to the lower surface of the substrate 100 than the lower surface 151_B of the first source/drain pattern 151. This is because the first well tap recess 161R and the first source/drain recess 151R have the same depth and the first barrier pattern 310 is positioned inside the first source/drain recess 151R.

In the embodiment, the thickness of the first well tap pattern 161 in the third direction (the Z direction) may be substantially the same as the thickness of the second source/drain pattern 152 in the third direction (the Z direction). For example, the upper surface of the first well tap pattern 161 may be positioned at the same level as that of the upper surface of the second source/drain pattern 152, and the lower surface 161_B of the first well tap pattern 161 may be positioned substantially at the same level as that of the lower surface of the second source/drain pattern 152. In other words, the lower surface 161_B of the first well tap pattern 161 and the lower surface of the second source/drain pattern 152 may be positioned substantially at the same distance from the lower surface of the substrate 100.

As shown in FIG. 22, in the second logic cell formation region PLC2, the second source/drain recess 152R may be formed by etching at least some portions of the upper pattern structure U_AP and the substrate 100 using the preliminary main gate electrode 131MP and the preliminary gate spacers 142P as a mask. Further, in the second tap cell formation region PTC2, a second well tap recess 162R may be formed by etching at least some portions of the upper pattern structure U_AP and the substrate 100 using the preliminary main gate electrode 131MP and the preliminary gate spacers 142P as a mask. Subsequently, the second source/drain pattern 152 may be formed inside the second source/drain recess 152R, and the second well tap pattern 162 may be formed inside the second well tap recess 162R.

In the embodiment, the second source/drain pattern 152 and the second well tap pattern 162 may have the first conductivity type. The second source/drain pattern 152 and the second well tap pattern 162 may be doped with a first conductivity type impurity. The first conductivity type may be a p-type. For example, the first conductivity type impurity may contain B, V, In, Ga, Al, or a combination thereof.

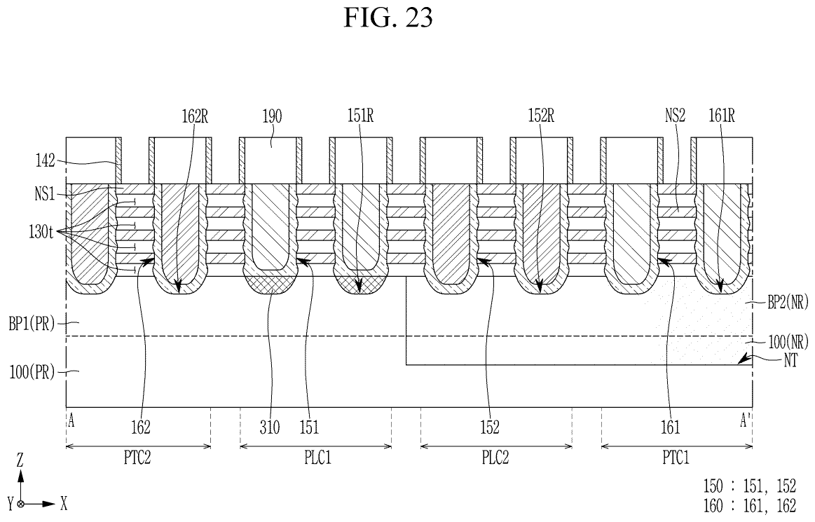

As shown in FIG. 23, first, the interlayer insulating layer 190 may be formed on the source/drain pattern 150 and the well tap pattern 160.

Subsequently, a portion of the interlayer insulating layer 190 and the preliminary capping layer 141P may be removed to expose the upper surface of the preliminary main gate electrode 131MP. In this case, some portions of the preliminary gate spacers 142P may be removed together, thereby forming the gate spacers 142.

Next, the preliminary gate insulating film 132P and the preliminary main gate electrode 131MP are removed to expose the channel patterns NS1 and NS2 between the gate spacers 142. Subsequently, the sacrifice patterns SC_L are removed, whereby a gate trench 130t is formed between the channel patterns NS1 and NS2.

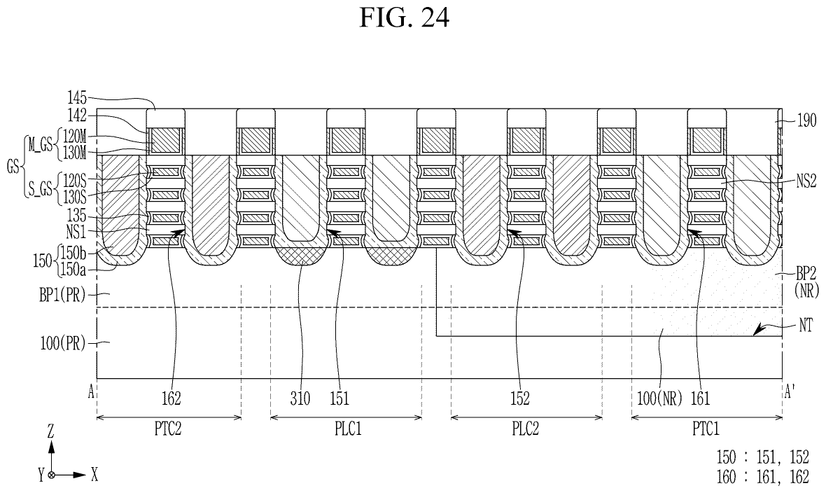

As shown in FIG. 24, inside the gate trench 130t, the sub gate insulating layer 130S and the sub gate electrode 120S may be sequentially formed. Further, the main gate insulating layer 130M and the main gate electrode 120M may be sequentially formed, whereby the gate structure GS may be formed. Furthermore, on the gate structure GS, the capping layer 145 may be formed.

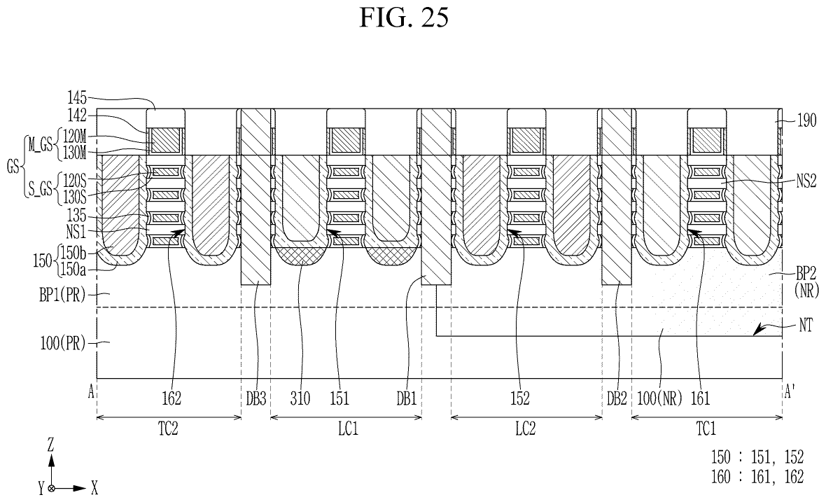

As shown in FIG. 25, the isolation structures DB1, DB2, and DB3 may be formed between the first logic cell formation region PLC1 and the second logic cell formation region PLC2, between the second logic cell formation region PLC2 and the first tap cell formation region PTC1, and the first logic cell formation region PLC1 and the second tap cell formation region PTC2.

The first isolation structure DB1 may be formed so as to pass through the capping layer 145, the gate structure GS, and the first lower pattern BP1 positioned between the first logic cell formation region PLC1 and the second logic cell formation region PLC2. The first isolation structure DB1 may recess at least a portion of the substrate 100.

The second isolation structure DB2 may be formed so as to pass through the capping layer 145, the gate structure GS, and the second lower pattern BP2 positioned between the second logic cell formation region PLC2 and the first tap cell formation region PTC1. The second isolation structure DB2 may recess at least a portion of the substrate 100.

The third isolation structure DB3 may be formed so as to pass through the capping layer 145, the gate structure GS, and the second lower pattern BP2 positioned between the first logic cell formation region PLC1 and the second tap cell formation region PTC2. The third isolation structure DB3 may recess at least a portion of the substrate 100.

As the isolation structures DB1, DB2, and DB3 are formed, the logic cells LC1 and LC2 and the tap cells TC1 and TC2 may be formed. In the embodiment, the logic cells LC1 and LC2 and the tap cells TC1 and TC2 may be isolated from each other by the isolation structures DB1, DB2, and DB3.

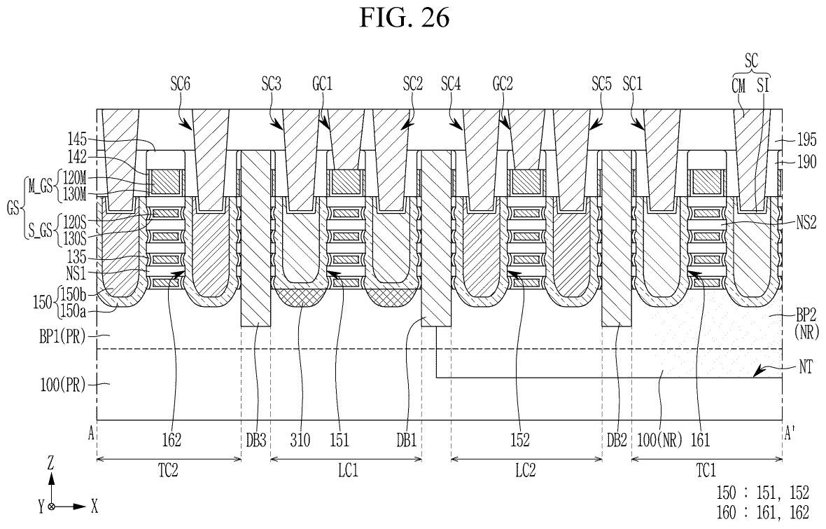

As shown in FIG. 26, the upper insulating layer 195 may be formed on the capping layer 145 and the interlayer insulating layer 190, and the contact electrode SC and the gate contact electrode GC may be formed so as to pass through the upper insulating layer 195 and the interlayer insulating layer 190, whereby the semiconductor device according to the embodiment may be formed.

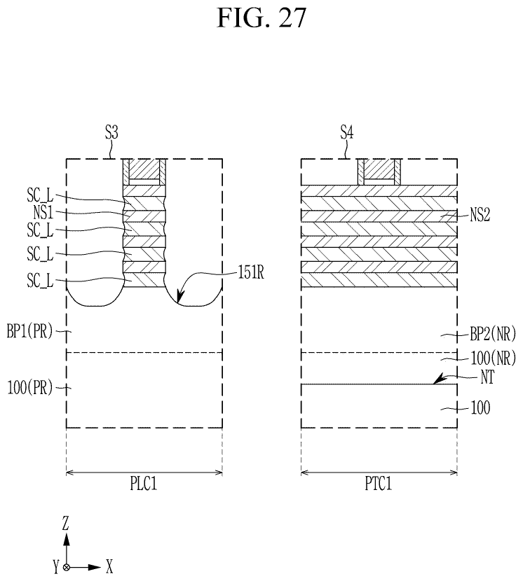

Hereinafter, a semiconductor device according to some example embodiments will be described with reference to FIGS. 27 to 30.

FIGS. 27 to 30 are cross-sectional views illustrating processes of an intermediate stage of a method of manufacturing the semiconductor device according to some example embodiments.

The embodiment shown in FIGS. 27 to 30 has much in common with the embodiment shown in FIGS. 15 to 26, and thus will be described with a focus on the differences without repeating descriptions. The embodiment of FIGS. 27 to 30 is different from the above embodiment in that the dummy barrier pattern 320 is formed.

As shown in FIG. 27, the first source/drain recess 151R may be formed by etching at least some portions of the upper pattern structure U_AP and the substrate 100.

In the first logic cell formation region PLC1, the first source/drain recess 151R may be formed by etching at least some portions of the upper pattern structure U_AP and the substrate 100 using the preliminary main gate electrode 131MP and the preliminary gate spacers 142P as a mask.

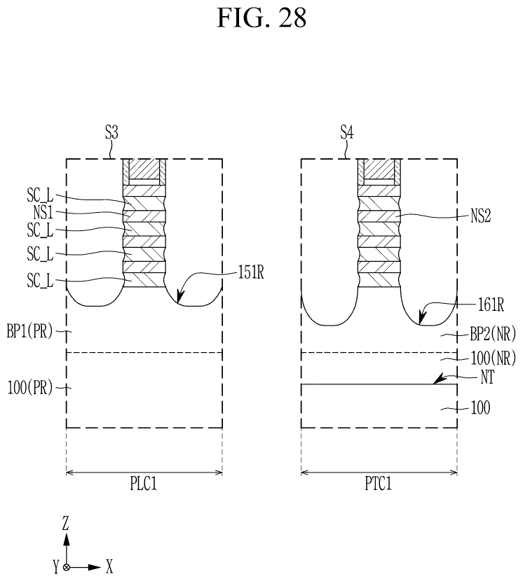

As shown in FIG. 28, the first well tap recess 161R may be formed by etching at least some portions of the upper pattern structure U_AP and the substrate 100.

In the first tap cell formation region PTC1, the first well tap recess 161R may be formed by etching at least some portions of the upper pattern structure U_AP and the substrate 100 using the preliminary main gate electrode 131MP and the preliminary gate spacers 142P as a mask. In some embodiments, the depth of the first well tap recess 161R in the third direction (the Z direction) may be deeper than the depth of the first source/drain recess 151R in the third direction (the Z direction). In other words, the bottom surface of the first well tap recess 161R may be positioned at a level lower than that of the bottom surface of the first source/drain recess 151R. The bottom surface of the first well tap recess 161R may be positioned closer to the lower surface of the substrate 100 than the bottom surface of the first source/drain recess 151R.

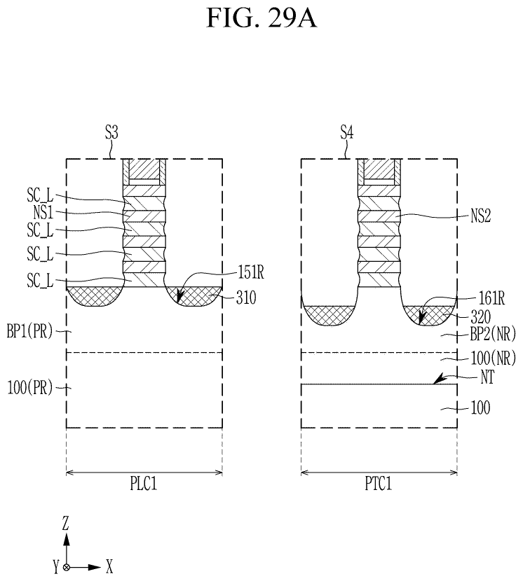

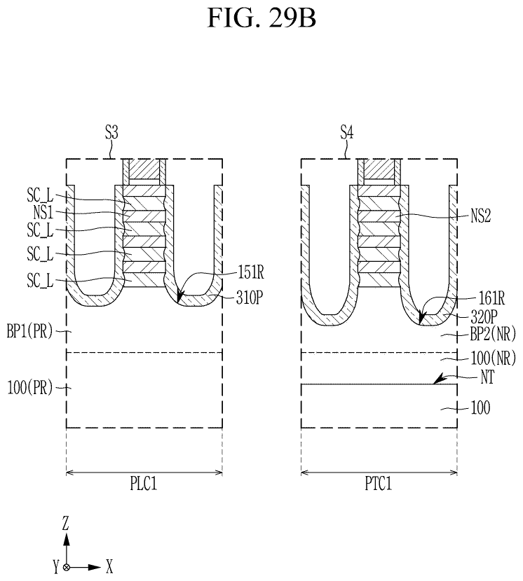

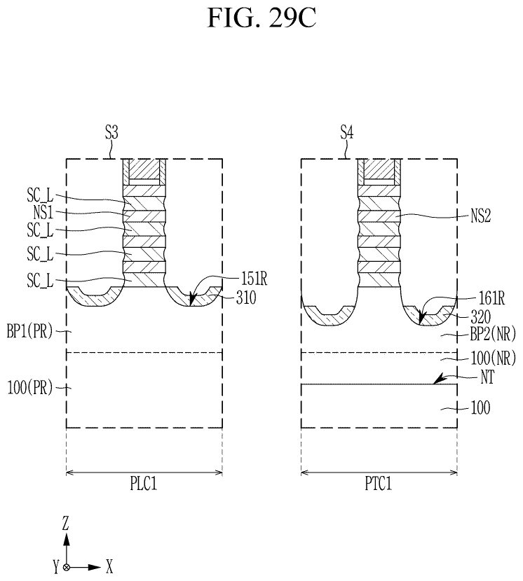

As shown in FIGS. 29A to 29C, the first barrier pattern 310 may be formed inside the first source/drain recess 151R, and the dummy barrier pattern 320 may be formed inside the first well tap recess 161R.

The first barrier pattern 310 may be formed in the first well region PR of the substrate 100. The first barrier pattern 310 may be formed on the first lower pattern BP1. The first barrier pattern 310 may fill a portion of the first source/drain recess 151R. The upper surface of the first barrier pattern 310 and the lower surface of the lowermost sacrifice pattern SC_L may be positioned substantially at the same boundary. Since the process of forming the first barrier pattern 310 is substantially identical to the process of forming the first barrier pattern 310 in the embodiment of FIGS. 18A to 18C, a detailed description thereof will not be made.

The dummy barrier pattern 320 may be formed in the second well region NR of the substrate 100. The dummy barrier pattern 320 may be formed on the second lower pattern BP2. The dummy barrier pattern 320 may fill a portion of the first well tap recess 161R. The upper surface of the dummy barrier pattern 320 may be positioned at a level lower than that of the lower surface of the lowermost sacrifice pattern SC_L. The upper surface of the dummy barrier pattern 320 may be positioned closer to the lower surface of the substrate 100 than the lower surface of the lowermost sacrifice pattern SC_L. Accordingly, at least a portion of the second lower pattern BP2 may be exposed.

In some embodiments, in this case, the thickness of the dummy barrier pattern 320 in the third direction (the Z direction) may be substantially the same as the thickness of the first barrier pattern 310 in the third direction (the Z direction); however, the present disclosure is not limited thereto. As another example, the thickness of the dummy barrier pattern 320 in the third direction (the Z direction) may be smaller than the thickness of the first barrier pattern 310 in the third direction (the Z direction).

The dummy barrier pattern 320 may contain various insulating materials. The dummy barrier pattern 320 may contain the same material as that of the first barrier pattern 310. For example, the dummy barrier pattern 320 may contain silicon boride (SiB). As another example, the dummy barrier pattern 320 may contain at least one of silicon oxide (SiO₂), silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

In an embodiment, as shown in FIG. 29A, the dummy barrier pattern 320 may be formed by an epitaxial growth method using the second lower pattern BP2 as a seed. As another example, the dummy barrier pattern 320 may be formed by depositing a dummy barrier pattern material layer 320P along the inner walls and bottom surface of the first well tap recess 161R as shown in FIG. 29B, and then removing at least a portion of the dummy barrier pattern material layer 320P as shown in FIG. 29C by performing an etching process. In this case, the process of removing at least a portion of the dummy barrier pattern material layer 320P may be performed using a wet etching process, but is not limited thereto.

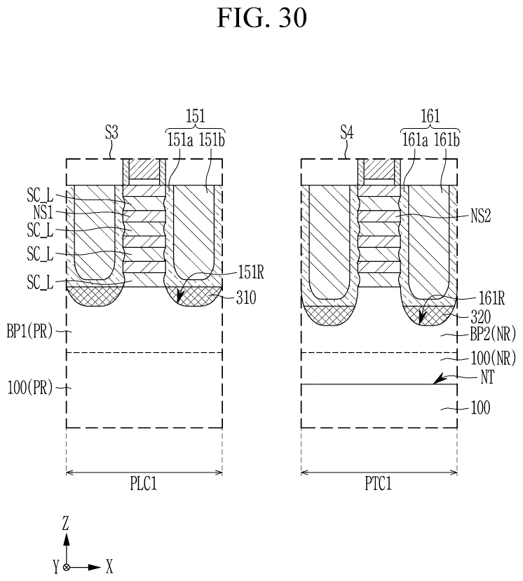

As shown in FIG. 30, the first source/drain pattern 151 may be formed inside the first source/drain recess 151R, and the first well tap pattern 161 may be formed inside the first well tap recess 161R, whereby the semiconductor device according to the embodiment of FIGS. 10 to 12 may be formed.

Although it has been described with reference to FIGS. 27 to 30 that after the first source/drain recess 151R and the first well tap recess 161R are formed, the first barrier pattern 310 and the dummy barrier pattern 320 are formed together, the present disclosure is not limited thereto. For example, after the first source/drain recess 151R is formed and the first barrier pattern 310 is formed inside the first source/drain recess 151R, the first well tap recess 161R may be formed and the dummy barrier pattern 320 may be formed inside the first well tap recess 161R. As another example, similarly to the embodiment of FIGS. 15 to 26, after the first source/drain recess 151R may be formed, the first barrier pattern 310 may be formed inside the first source/drain recess 151R, and the first source/drain pattern 151 is formed, the first well tap recess 161R may be formed, the dummy barrier pattern 320 may be formed, and the first well tap pattern 161 may be formed.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor device comprising:
a substrate that includes a first well region having a first conductivity type and a second well region having a second conductivity type;
a first lower pattern positioned in the first well region;
a second lower pattern positioned in the second well region;
a first channel pattern positioned on the first lower pattern;
a second channel pattern positioned on the second lower pattern;
a gate structure that surrounds the first channel pattern and the second channel pattern;
a first source/drain pattern positioned on opposite sides of the first channel pattern;
a first well tap pattern positioned on opposite sides of the second channel pattern; and
a first barrier pattern positioned between the first source/drain pattern and the first lower pattern.

2. The semiconductor device of claim 1, wherein the first source/drain pattern and the first well tap pattern have the second conductivity type.

3. The semiconductor device of claim 1, wherein at least a portion of the first well tap pattern is in contact with the second lower pattern.

4. The semiconductor device of claim 1, wherein a lower surface of the first source/drain pattern is positioned farther from a lower surface of the substrate than a lower surface of the first well tap pattern.

5. The semiconductor device of claim 1, wherein the first source/drain pattern and the first lower pattern are positioned so as to be spaced apart.

6. The semiconductor device of claim 1, wherein a lower surface of the first barrier pattern and a lower surface of the first well tap pattern are positioned at the same distance from a lower surface of the substrate.

7. The semiconductor device of claim 6, wherein an upper surface of the first barrier pattern and a lower surface of the gate structure are positioned at the same distance from the lower surface of the substrate.

8. The semiconductor device of claim 6, wherein a thickness of the first barrier pattern is different from a distance between a lower surface of the gate structure and the lower surface of the first well tap pattern.

9. The semiconductor device of claim 1, wherein at least a portion of the first barrier pattern overlaps the gate structure in a horizontal direction.

10. The semiconductor device of claim 1, further comprising:
a void that is positioned between the first barrier pattern and the first source/drain pattern,
wherein the void is positioned so as to be spaced apart from the gate structure.

11. The semiconductor device of claim 1, further comprising:
a dummy barrier pattern positioned between the first well tap pattern and the second lower pattern,
wherein an upper surface of the dummy barrier pattern is positioned closer to a lower surface of the substrate than an upper surface of the first barrier pattern.

12. The semiconductor device of claim 11, wherein the dummy barrier pattern contains the same material as that of the first barrier pattern.

13. The semiconductor device of claim 11, wherein a lower surface of the dummy barrier pattern is positioned closer to the lower surface of the substrate than a lower surface of the first barrier pattern.

14. The semiconductor device of claim 11,
wherein at least a portion of the first well tap pattern is in contact with the second lower pattern, and
wherein a thickness of the dummy barrier pattern is the same as a thickness of the first barrier pattern.

15. The semiconductor device of claim 1, further comprising:
a second source/drain pattern positioned on opposite sides of the second channel pattern between the first source/drain pattern and the first well tap pattern and has the first conductivity type,
wherein a portion of the second source/drain pattern is electrically connected to the first source/drain pattern, and the other portion is electrically connected to the first well tap pattern.

16. The semiconductor device of claim 15, further comprising:
a second barrier pattern positioned between the second source/drain pattern and the second lower pattern,
wherein a lower surface of the second barrier pattern and a lower surface of the first well tap pattern are positioned at the same distance from a lower surface of the substrate.

17. A semiconductor device comprising:
a substrate that includes a first well region having a first conductivity type and a second well region having a second conductivity type;
a first lower pattern positioned in the first well region;
a second lower pattern positioned in the second well region;
a first channel pattern positioned on the first lower pattern;
a second channel pattern positioned on the second lower pattern;
a gate structure that surrounds the first channel pattern and the second channel pattern;
a first source/drain pattern positioned on opposite sides of the first channel pattern and has the second conductivity type;
a first well tap pattern positioned on opposite sides of the second channel pattern and has the second conductivity type; and
a first barrier pattern positioned between the first source/drain pattern and the first lower pattern,
wherein a thickness of the first source/drain pattern is smaller than a thickness of the first well tap pattern.

18. The semiconductor device of claim 17, wherein a thickness of the first barrier pattern is the same as a distance between a lower surface of the gate structure and a lower surface of the first well tap pattern.

19. A semiconductor device comprising:
a substrate that includes a first well region having a first conductivity type and a second well region having a second conductivity type;
a first tap cell that is positioned in the first well region and has the second conductivity type; and
a first logic cell that is positioned in the second well region and has the second conductivity type,
wherein the first logic cell includes the following:
a first lower pattern positioned in the first well region;
a first channel pattern positioned on the first lower pattern;
a gate structure that surrounds the first channel pattern;
a first source/drain pattern positioned on opposite sides of the first channel pattern; and
a first barrier pattern positioned between the first source/drain pattern and the first lower pattern,
wherein the first tap cell includes the following:
a second lower pattern positioned in the second well region;
a second channel pattern positioned on the second lower pattern; and
a first well tap pattern positioned on opposite sides of the second channel pattern and is in contact with the second lower pattern, and
wherein a lower surface of the first barrier pattern is positioned farther from a lower surface of the substrate than a lower surface of the first well tap pattern, or the lower surface of the first barrier pattern and the lower surface of the first well tap pattern are positioned at the same distance from the lower surface of the substrate.

20. The semiconductor device of claim 19, further comprising:
a second logic cell that is positioned between the first tap cell and the first logic cell in the second well region, has the first conductivity type, and includes a second source/drain pattern which is positioned on opposite sides of the second channel pattern; and
a second tap cell that is positioned in the first well region, has the first conductivity type, and includes a second well tap pattern which is positioned on opposite sides of the first channel pattern,
wherein the first source/drain pattern and the first well tap pattern contain the same material, and
wherein the second source/drain pattern and the second well tap pattern contain the same material.
